(19) United States
(12) Patent Application Publication
(10) Pub. No.: US 2008/0124484 A1
(43) Pub. Date: May 29, 2008

(54) METHOD OF FORMING RU FILM AND METAL WIRING STRUCTURE

(75) Inventors: Hiroshi SHINRIKI, Tokyo (JP); Hiroaki INOUE, Tokyo (JP)

Correspondence Address: KNOBBE MARTENS OLSON & BEAR LLP, 2040 MAIN STREET, FOURTEENTH FLOOR, IRVINE, CA, 92614, US

(73) Assignee: ASM JAPAN K.K., Tokyo (JP)

(21) Appl. No.: 11/557,891

(22) Filed: Nov. 8, 2006

(51) Int. Cl. C23C 16/00; C23C 16/513

(52) U.S. Cl. 427/535; 427/250

(57) ABSTRACT

A method of depositing a ruthenium (Ru) thin film on a substrate includes: (i) treating a surface of the substrate with a metal-organic precursor; (ii) adsorbing a ruthenium precursor onto the treated surface of the substrate; (iii) treating the adsorbed ruthenium precursor with an excited reducing gas; and (iv) repeating steps (ii) and (iii), thereby forming a ruthenium thin film on the substrate.

### BACKGROUND OF THE INVENTION

1. Field of the Invention

The present invention generally relates to a method of forming Ru films and metal wring structures that can be used favorably in producing fine semiconductor devices.

2. Description of the Related Art

Ru films are drawing the attention because by forming a Ru film at the interface of Cu and barrier metal in a Cu wiring structure, which is the mainstream wiring structure used with high-speed logic devices such as MPUs, the Ru film can provide improved adhesion with Cu and thus significantly improve the reliability of wiring. Methods to form a Ru film on a TaN film or WN film, which is a Cu diffusion barrier metal, and then form a Cu film on top of the Ru film, are being examined (refer to C-C Yong et al., IITC 2006, pp. 187-189, “Physical, Electrical, and Reliability Characterization of Ru for Cu Interconnects” for an example of such method on a Ru/TaN combination). Specifically, application of a Cu liner consisting of a layered structure of Ru/TaN, etc., is examined.

A Cu liner film, such as Ru/TaN, which is being examined for use as a Cu wiring liner, tends to produce higher Cu wiring resistance if the film is thicker, because a thicker film results in a smaller Cu wiring volume. This creates a need to make the film as thin as possible. In a layered structure consisting of a copper-diffusion barrier film and a Ru film, however, making the Ru film thinner virtually prevents formation of a continuous film, resulting in the barrier film being exposed partially. As a result, an interface of Cu wiring and barrier film is produced, which can cause problems. If the Ru film is made thicker to form a continuous film, on the other hand, the Cu wiring resistance increases. In other words, formation of a thin, continuous Ru film is desired. Also, when forming a Ru film on a copper-diffusion barrier film such as a TaN film, TaNC film, etc., the Ru film needs to be formed in a reducing atmosphere to prevent the aforementioned barrier film from being oxidized.

According to US2006/0177601A, a Ru film can be formed in a reducing atmosphere by means of a step of supplying a Ru material that contains a ligand containing a cyclopentadienyl group, and a treatment step using NH3 gas activated by high-frequency waves.

### SUMMARY OF THE INVENTION

Although a WNC film is an excellent copper-diffusion barrier film, forming a Ru/WNC layered structure makes the Ru film thin, thus making the film virtually non-continuous and therefore causing the WNC film to become partially exposed easily. The inventors utilized the process disclosed in US2006/0177601A to form a 3-nm Ru film on a WNC film, after which a copper seed layer was formed along with a plating layer, followed by a CMP process over the wiring. As a result, the underlying WNC film was etched because the Ru film was not continuous, and the Ru film peeled off. A Ru film does not easily become a continuous film unless the film has a certain thickness (approx. 3 to 4 nm). For this reason, a continuous Ru film does not easily form when a Ru film is layered with a copper wiring and a WNC film that serves as a barrier film, or with a copper barrier film such as a TaN film, TaNC film or WN film, in which case the Ru film cannot be applied as a copper diffusion barrier. As a result, it is necessary to give the underlying barrier film a sufficient thickness.

From the aforementioned viewpoint, the inventors developed a technology to form a continuous Ru film with a thickness of approx. 1 nm by repeating a step of introducing a Ru material molecule containing at least one cyclopentadienyl group, and another step where NH3 or H2 plasma treatment is performed (U.S. patent application Ser. No. 11/469,828 owned by the same assignee as in the present application, the disclosure of which is incorporated herein by reference in its entirety).

Using the aforementioned material, however, it was still difficult to form a Ru film directly on an insulated film made of SO2, etc. Therefore, the inventors conducted studies and found that a Ru film could be formed easily by exposing a metal-organic precursor such as Ta, Ti, Hf, Nb or Zr to the surface of the insulation film prior to the Ru forming process. Also, it was found that a Ru film would be formed easily by repeating at least once a step of introducing the above material and a plasma step using a reducing gas such as NH3 or H2, thereby forming a thin film containing Ta, Ti, Hf, Nb, Zr, etc., on an insulation film. In addition, it becomes possible to further suppress the diffusion of Cu from the grain boundary in the Ru film by adding Ta, Ti, Zu, Hf, Nb or Al to the Ru film.

In an embodiment, the present invention provides a method of depositing a ruthenium (Ru) thin film on a substrate, comprising: (i) treating a surface of the substrate with a metal-organic precursor; (ii) adsorbing a ruthenium precursor onto the treated surface of the substrate; (iii) treating the adsorbed ruthenium precursor with an excited reducing gas; and (iv) repeating steps (ii) and (iii), thereby forming a ruthenium thin film on the substrate.

The above embodiment further includes, but is not limited to, the following embodiments.

In an embodiment, step (i) may comprise exposing the surface of the substrate to a gas of the metal-organic precursor to adsorb the metal-organic precursor on the substrate surface. In an embodiment, the metal-organic precursor may contain Ta, Hf, Zr, or Ti.

In an embodiment, step (i) may comprise (a) adsorbing the metal-organic precursor onto the surface of the substrate; (b) treating the adsorbed metal-organic precursor with a reactive gas; and (c) repeating steps (a) and (b), thereby forming a metal film on the substrate. In an embodiment, the metal film may contains W, Ta, Hf, Zr, or Ti. In an embodiment, the metal film may be formed by atomic layer deposition (ALD). The metal film may be selected from the group consisting of TaN, TaNC, TiN, and TiNC.

In an embodiment, the ruthenium precursor may be a ruthenium complex containing a non-cyclic dienyl. In an embodiment, the ruthenium complex may have a structure of Xa-Ru-Xb, wherein at least one of Xa or Xb is a non-cyclic dienyl. In an embodiment, the non-cyclic dienyl may be a non-cyclic pentadienyl.

In an embodiment, the excited reducing gas may be generated by applying radio-frequency power to a reducing gas. In an embodiment, the reducing gas may be ammonia, hydrogen, or a mixture of nitrogen and hydrogen. In an embodiment, the excited reducing gas may be an ammonia or hydrogen plasma.

In an embodiment, the method may further comprise purging the ruthenium precursor gas from a reaction chamber after step (ii) and purging the excited reducing gas from the reaction chamber after step (iii).

In an embodiment, steps (ii) and (iii) may be repeated to form the ruthenium thin film having a thickness of no less than 0.5 nm but no more than 2.0 nm by atomic layer deposition (ALD).

In an embodiment, the ruthenium thin film may be formed on and in contact with the underlying layer formed by step (i), wherein a thickness of the ruthenium thin film is greater than that of the underlying layer.

In an embodiment, the method may further comprise treating the substrate surface with a metal-organic precursor after step (iv) and resuming step (iv). In an embodiment, the metal-orgnic precursor may contain Al, Ti, Ta, Hf, Nb, or Zr. In an embodiment, steps (i) to (iv) may be repeated to form a layered structure.

All of the embodiments described above can be employed in any combination.

For purposes of summarizing the invention and the advantages achieved over the related art, certain objects and advantages of the invention are described in the present disclosure. Of course, it is to be understood that not necessarily all such objects or advantages may be achieved in accordance with any particular embodiment of the invention. Thus, for example, those skilled in the art will recognize that the invention may be embodied or carried out in a manner that achieves or optimizes one advantage or group of advantages as taught herein without necessarily achieving other objects or advantages as may be taught or suggested herein.

Further aspects, features and advantages of this invention will become apparent from the detailed description of the preferred embodiments which follow.

### BRIEF DESCRIPTION OF THE DRAWINGS

These and other features of this invention will now be described with reference to the drawings of preferred embodiments which are intended to illustrate and not to limit the invention.

FIG. 1(a) and FIG. 1(b) are diagrams illustrating the pre-treatment process, implemented prior to forming a Ru film in one embodiment of the present invention.

FIG. 2(a) is a diagram illustrating a process that is repeated to form a Ru film, implemented in one embodiment of the present invention.

FIG. 2(b) is a diagram illustrating a process that is repeated to form a Ru film on a metal film, implemented in one embodiment of the present invention.

FIG. 3(a) is a chemical formula of a Ru precursor that can be used in one embodiment of the present invention.

FIG. 3(b) is a chemical formula of another Ru precursor that can be used in one embodiment of the present invention.

FIG. 3(c) is a chemical formula of a Ru precursor used in a prior art.

FIG. 9 is a schematic diagram illustrating a thin-film forming apparatus that can be used to implement the present invention.

FIG. 10(a) and FIG. 10(b) are schematic diagrams illustrating a method to evaluate the continuity of a Ru film, where the Ru film shown in FIG. 10(a) is non-continuous, while the Ru film shown in FIG. 10(b) is continuous.

FIG. 11 is a graph showing one example of the dependency of Ru growth speed on number of cycles, when the Ru material shown in FIG. 3(a), (b) or (c) is used.

FIG. 12 is a graph showing one example of the relationship of the film forming cycles with the Ru film formed in FIG. 11, and the amount of W detected from the underlying layer, when the method illustrated in FIGS. 10(a) and (b) is used.

FIGS. 13(a), (b), (c), (d), (e) and (f) provide a schematic diagram illustrating a process flow ((a)→(b)→(c)→(d)→(e)→(f)) of applying a Ru-film forming process conforming to one example of the present invention to a dual-damascene Cu wiring process. Take note that the film thickness is not scaled. Particularly in this example, the pre-treatment layer 209 is an atom-molecule layer having an atom-adsorbed structure, and is substantially thinner than the Ru film 210, etc.

FIG. 14(a) is a diagram illustrating the dual-damascene Cu wiring process (surface treatment→MO pre-treatment→Ru film forming) shown in FIG. 13 as used in one embodiment of the present invention, while FIG. 14(b) is a structural diagram illustrating one example of a vacuum-cycle cluster apparatus used to implement the aforementioned process.

FIGS. 15(a), (b), (c), (d), (e) and (f) provide a schematic diagram illustrating a process flow ((a)→(b)→(c)→(d)→(e)→(f)) of applying a series of continuous steps including surface treatment, MO ALD step (pre-treatment) and Ru film forming, conforming to one example of the present invention, to a dual-damascene Cu wiring process. Take note that the film thickness is not scaled. Particularly in this example, the pre-treatment layer 409 is an ALD film formed using a gas of a metal-organic precursor, and is substantially thinner than the Ru film 410, etc.

FIG. 16(a) is a diagram illustrating the dual-damascene Cu wiring process shown in FIG. 15 as used in one embodiment of the present invention, while FIG. 16(b) is a structural diagram illustrating one example of a vacuum-cycle cluster apparatus used to implement the aforementioned process.

FIG. 17 is a schematic diagram of a thin-film forming apparatus that can be used to implement the present invention.

FIGS. 18(a), (b), (c), (d), (e) and (f) provide a schematic diagram illustrating a process flow ((a)→(b)→(c)→(d)→(e)→(f)) of applying a series of continuous steps including surface treatment, MO ALD step (pre-treatment) and MO-Ru film forming, conforming to one example of the present invention, to a dual-damascene Cu wiring process. Take note that the film thickness is not scaled. Particularly in this example, the pre-treatment layer 209 is an atom-molecule layer having an atom-adsorbed structure, and is substantially thinner than the Ru film 210, etc. Also in this example, the Ru film 612 is equivalent to the Ru film 210.

FIG. 19(a) is a diagram illustrating the dual-damascene Cu wiring process shown in FIG. 18 as used in one embodiment of the present invention, while FIG. 19(b) is a structural diagram illustrating one example of a vacuum-cycle cluster apparatus used to implement the aforementioned process.

### DESCRIPTION OF THE SYMBOLS

1: Chamber

2: Upper lid

3: Dispersion plate

4: Exhaust duct

5: Lower chamber

6: Substrate transfer gate

7: Exhaust port

8: Substrate heater

9: Substrate-heater up/down bellows

10: Gas introduction piping

11: Gas introduction part

12: Radical source

13: Gas dispersion guide

14: Space between the gas dispersion part 13 and the dispersion plate 3

15: Substrate

16: Radical-source connection valve

17: Slit continuing from the gas dispersion guide to the exhaust port

18: Space continuing to the exhaust port

19: Connection flange for exhaust

20: Exhaust valve continuing into the showerhead

21: Gas discharge port provided on the dispersion plate 3

22: Space between the dispersion plate 3 and the substrate

23: Ring slit

24: Exhaust pipe continuing to the ring slit

25: High-frequency wave introduction terminal

26: Pressure control part

27: Molecular-pump gate valve

28: Evacuation gate valve

29: Molecular pump

30: Dry pump

31: Bellows-purge gas introduction valve

201: Lower-layer copper wiring

202: Copper-diffusion prevention layer

203: Interlayer insulation film 1

204: Etching stopper layer

205: Interlayer insulation film 2

206: Copper-diffusion prevention film

207: Via

208: Trench

209: WNxCy film

210: Ru-ALD film

211: Cu seed film

212: Copper wiring

300: Silicon-substrate introduction port

301: Silicon-substrate transfer unit

302: Load lock chamber

303: Vacuum transfer chamber

304: Pre-cleaning module

305: Taimata pre-treatment module

306: Ru-ALD forming module

409: TaNC film

410: Ru film

505: ALD module for forming Ta, Ti or W film

506: Ru-ALD module

101: Chamber

102: Gate valve

103: Exhaust duct

104: Shower plate

105: Gas introduction port to the lower gas dispersion chamber

106: Gas discharge port from the lower gas dispersion chamber

107: Lower gas dispersion chamber

108: Gas guide for the upper gas dispersion chamber

109: Exhaust valve for the upper gas dispersion chamber

110: Center gas pipe for mixing gases

111: Gas dispersion plate

112: Gas discharge port from the upper gas dispersion chamber

113: Upper lid plate

114: Substrate-heating table up/down bellows

115: Substrate

120: Ru material-gas purge valve

121: Ru material-gas introduction valve

122: Gas for purging the center gas pipe for mixing gases

123: Material-gas (NH3 or O2) purge gas valve

124: Material-gas (NH3 or O2) introduction valve

125: Exhaust-side main valve

126: Pressure control part

127: Molecular-pump gate valve

128: Evacuation gate valve

129: Molecular pump

130: Dry pump

131: Bellows-purge gas introduction valve

132: Exhaust valve continuing to the dispersion chamber 7

133: Carrier-gas introduction valve to the Ru material container

134: Ru-material supply valve from the Ru material container

135: Ru material container

136: Carrier-gas introduction valve to the Taimata material container

137: Taimata supply valve from the Taimata material container

139: Taimata material container

140: Taimata introduction valve

611: TaNC film formed over one to 30 cycles

612: Ru film

605: Module capable of forming Ru-PEALD, TaNC or TiNC-PEALD

606: Module capable of forming Ru-PEALD, TaNC or TiNC-PEALD

### DETAILED DESCRIPTION OF THE PREFERRED EMBODIMENT

The present invention will be explained with reference to preferred embodiments and drawings. However, the preferred embodiments and drawings are not intended to limit the present invention.

One embodiment of the present invention relates to a pre-treatment whereby Ru growth is promoted to a level beyond a WNC or WN film, which is a barrier metal film used to form a Ru film, so that a continuous film is formed at a small thickness. Since a very thin but continuous Ru film can be formed, the Ru film itself can prevent diffusion of Cu even when the thickness of the barrier metal film, such as a copper-diffusion barrier film formed under a prior art, is reduced from a level generally used in a prior art.

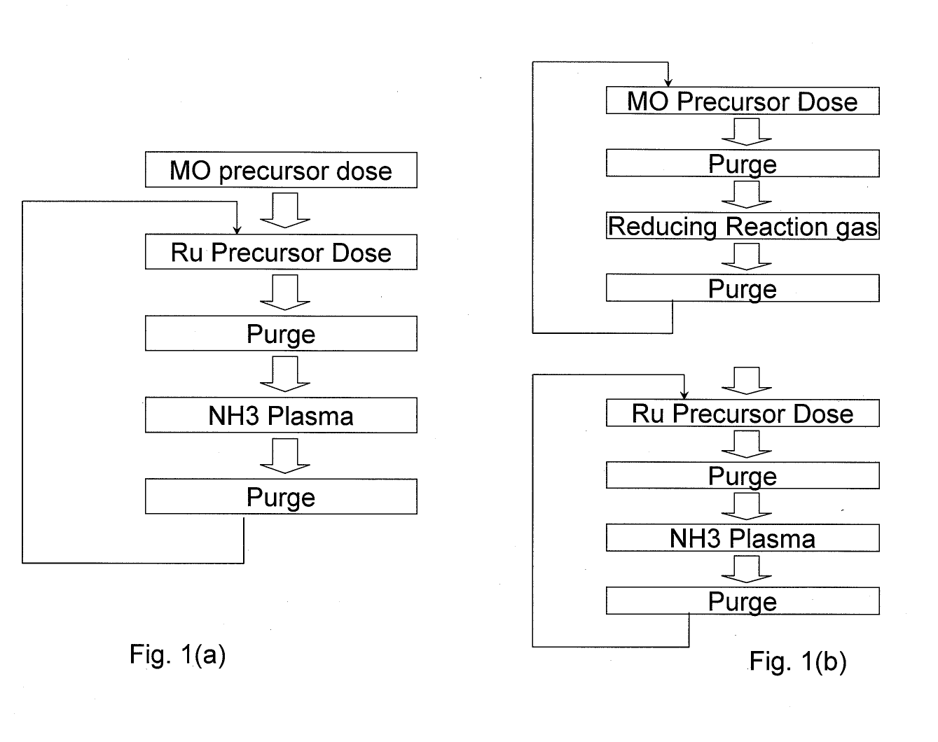

In one embodiment, before implementing the process of forming Ru on an insulation film such as SO2, SiOC, SiN, SiNC or SiC, a continuous thin Ru film can be formed easily by forming a Ru film after exposing a metal-organic precursor such as Ta, Ti, Hf, Nb or Zr to the surface of an oxide film, as shown in FIG. 1(a). In another embodiment, a step of introducing the above material, and a plasma step using a reducing gas such as NH3 or H2, are repeated at least once to form a thin film containing Ta, Ti, Hf, Nb, Zr, etc., in order to form a Ru, so that the Ru film can be easily made a continuous thin film. In yet another embodiment, Ta, Ti, Zu, Hf, Nb, Al, etc., can be added to the Ru film to further suppress the diffusion of Cu from the grain boundary in the Ru film.

In the aforementioned embodiment, a Ru film is formed after a treatment using a metal-organic precursor or after forming a very thin metal film, or a Ru film is formed by adding Ta, Ti, Zu, Hf, Nb, Al, etc., to use the Ru film itself as a barrier film, which is effective in reducing the thickness of the barrier film itself and also results in lower wiring resistance. In addition, good adhesion with Cu can be achieved, which has the effect of enhancing wiring reliability.

In one embodiment, the pre-treatment uses the atomic layer deposition method or plasma atomic layer deposition method, where the number of atomic layer deposition cycles is one or more but no more than 50 cycles, while the film thickness is no less than 1 but no more than 2 nm, or preferably no more than 1 nm. By forming the aforementioned Ru film in a manner thicker than the pre-treatment layer, or specifically with a thickness in a range of approx. 1 nm to approx. 3 nm (or preferably approx. 1 nm to approx. 2 nm), diffusion of copper can be prevented. Unlike the conventional notion of preventing copper diffusion using a TaN, TaNC, WN or WNC barrier film thicker than a Ru film, the main idea here is to prevent copper diffusion using the Ru film itself and also form an underlying film, with an adhesive layer, in a pre-treatment step of promoting the formation of Ru film. Therefore, there is no need to provide this underlying layer for the Ru film in the form of a film, and it is sufficient that some kind of surface treatment is given to the underlying surface to create a condition where a Ru film can be formed easily. In this case, there is no need to perform atomic layer deposition cycles to form a barrier film, and a Ru film can be grown simply by means of causing a pre-treatment gas to adsorb to the substrate surface and thereby using the adsorbed gas as a core around which to form a Ru film. For example, supplying a metal-organic precursor containing Ta, Hf, Zr, Ti or Nb to an insulation film surface and then performing a Ru-PEALD process can form a Ru film comparable to a Ru film formed on a barrier film.

Table 1 shows one example of a set of conditions used for adsorbing the gas of a metal-organic precursor to an insulator surface in the process shown in FIG. 1(a). There are no specific limitations to the conditions, as long as the conditions allow metal atoms to be adsorbed uniformly over the insulator surface. In general, once metal atoms have adsorbed over the entire surface, continuing the process for any longer period of time does not build the layer further.

TABLE 1

| | Flow rate | | | |
|---|---|---|---|---|
| Phase | (Sccm) | Temp. (° C.) | Pressure (Pa) | Time (sec) |
| MO precursor | 100–1000 | 200–400 | 100–500 | 1–100, |
| | preferably | preferably | preferably | preferably |
| | 300–500 | 300–350 | 200–400 | 1–10 |

In one embodiment, a metal-organic precursor containing Ta, Ti, Hf, Nb, Zr, etc., can be used. For example, Taimata (Tertiaryamylimidotrid(dimethylamido)tantalum), as well as Ta(N-t-C4H9)[N(C2H5)2]3, Ta[N(CH3)2]5, Ta[N(C2H5)2]5, Hf[N(CH3)2]4, Hf[N(C2H5)2]4, Ti[N(CH3)2]4, Ti[N(C2H5)2]4, Zr[N(CH3)2]4, Zr[N(C2H5)2]4, Nb[N(CH3)2]5 and Nb[N(C2H5)2]5, can be used, among others.

Table 2 shows one example of a set of conditions used for implementing film formation cycles (pre-treatment) where a film is formed on an insulator surface using a gas of a metal-organic precursor in the process shown in FIG. 1(b). There are no specific limitations to the conditions, as long as the conditions allow a metal atomic film to be formed virtually as a continuous film.

TABLE 2

| | Flow rate | Temp. | | |
|---|---|---|---|---|
| Phase | (Sccm) | (° C.) | Pressure (Pa) | Time (sec) |
| MO dose | 100–1000 | 200–400 | 100–500 | 1–5 preferably |
| | preferably | preferably | preferably | 1–2 |
| | 300–500 | 300–350 | 200–400 | |
| Purge | 300–2000, | 200–400 | 100–500, | 0.5–2 |
| | preferably | preferably | preferably | preferably |
| | 500–2000 | 300–350 | 100–300 | 0.5–1 |
| Reducing gas | 300–1000 | 200–400 | 100–400 | 1–10, |
| Plasma | preferably | preferably | preferably | preferably |
| | 500–1000 | 300–350 | 150–300 | 2–6 |
| Purge | 300–2000, | 200–400 | 100–500, | 0.5–2 |
| | preferably | preferably | preferably | preferably |
| | 500–2000 | 300–350 | 100–300 | 0.5–1 |

In one embodiment, one to 30 cycles, or preferably five to 20 cycles, are performed, and the film thickness is approx. 2 nm or less, such as in a range of approx. 0.03 to 2.0 nm, or preferably 0.5 to 1.0 nm. As for the metal material gas, any of the gases that can be used in the pre-treatment shown in FIG. 1(a) can also be used in the pre-treatment shown in FIG. 1(b). The reducing gas plasma may be NH3 or H2 plasma, for example, and the RF voltage can be set to 200 to 1,000 W (or preferably 400 to 800 W), for example. The purge gas may be Ar, He, N2, etc.

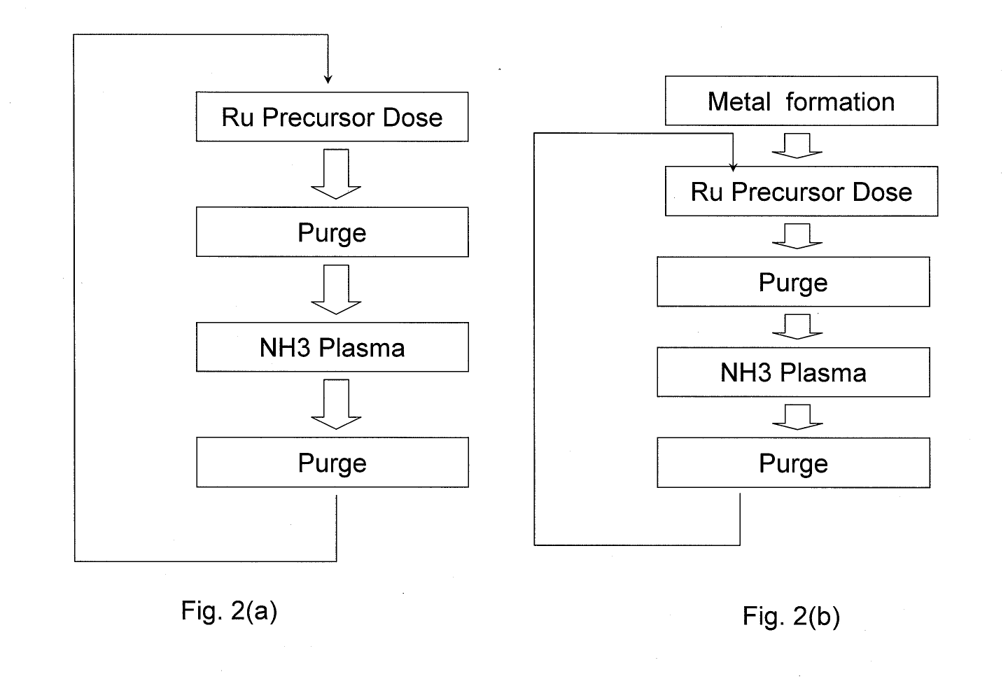

Next, formation of Ru film is explained. In one embodiment of the present invention, a Ru-film forming process is implemented in a reducing atmosphere so that a Ru film can be formed on a pre-treatment layer without oxidizing the aforementioned pre-treatment layer. As shown in FIG. 2(a), a Ru film can be formed in a reducing atmosphere by repeating a step of introducing a Ru precursor to the substrate surface; a step of purging the unnecessary Ru precursor; a step of treating the Ru precursor adsorbed to the substrate surface using a plasma gas generated by applying high-frequency waves to a reducing gas containing at least NH3 or H2, etc.; and a step of purging the reducing gas. This way, a Ru film can be formed without oxidizing the top surface of the pre-treatment layer. FIG. 2(b) shows a sequence through which to form a Ru film on a metal film constituted by WNC or TaN using a similar method. In one embodiment of the present invention, a pre-treatment layer is provided in place of the aforementioned metal layer.

Under the conditions for the process shown in FIG. 2(a), a Ru material gas is supplied onto a substrate first. At this time, the Ru material is heated to a temperature range of approx. 80 to 120° C. (including 90° C., 100° C., 110° C. and other temperatures in between), and the generated vapor of the Ru material is introduced into a reaction apparatus by means of an inactive gas (such as Ar). The flow rate of the inactive gas may be in a range of approx. 100 to 700 sccm (including 200 sccm, 300 sccm, 400 sccm, 500 sccm, 600 sccm and other flow rates in between, or preferably between 300 and 500 sccm). The vapor pressure of the Ru material should be adjusted to a range of approx. 0.1 to 2 torr (including 0.5 torr, 1.0 torr, 1.5 torr and other pressures in between). In this embodiment, the aforementioned flow rate of Ru refers to the flow rate of the carrier gas (inactive gas) containing Ru, which is used to carry the Ru material vapor produced by vaporizing the material at the above vapor pressure. Also, the supply piping should be heated to a temperature of 130° C. or above, such as 150° C. or so, to prevent the vaporized material from liquefying. Take note that the ALD process is a self-saturating process, and an ALD film can be formed on a substrate under the above conditions.

Next, in one embodiment the above gas is purged (using an inactive gas at a flow rate of 1,000 to 3,000 sccm), after which a reducing gas is excited using high-frequency waves to treat the Ru film surface. As the conditions to do this, NH3 gas can be supplied at a flow rate in a range of 200 to 700 sccm (or preferably 300 to 500 sccm), at a high-frequency output in a range of 200 to 1,000 W (including 300 W, 500 W, 700W and other outputs in between) based on high-frequency waves of 13.56 kHz. As for the inactive gas, desirably Ar should be supplied at a flow rate in a range of 300 to 2,000 sccm (or preferably 500 to 1,200 sccm). The pressure condition can be adjusted to an optimal level between 1 and 3 torr. In one embodiment, the aforementioned reducing gas may be NH3, H2, a mixture of N2 and H2, or a mixture gas containing any of the foregoing.

In one embodiment, a step of supplying the aforementioned Ru material gas to a substrate, and a step of treating the aforementioned substrate using a reducing gas excited by high-frequency waves, are repeated to form a Ru film with a thickness of 3 nm or less, such as no less than 0.5 nm but no more than 2.5 nm, or preferably no less than 1.0 nm but no more than 2.0 nm.

In one embodiment, a step of supplying the aforementioned Ru material gas to a substrate, and a step of treating the top surface of the aforementioned substrate using a gas containing at least NH3 or H2 excited by high-frequency waves, are repeated for no less than 50 cycles but no more than 150 cycles, or preferably no less than 75 cycles but no more than 100 cycles, to form the aforementioned Ru film. In other words, a film with a thickness of no less than 0.5 nm but no more than 2.0 nm can be formed by repeating the above steps for no less than 50 cycles but no more than 150 cycles. Here, the number of cycles needed to achieve a specified film thickness of 1 to 2 nm changes depending on the type of Ru material.

Any Ru material gas can be used favorably as long as it can form a continuous Ru film. The continuity of a Ru film formed on a metal film is affected by the structure of the Ru material molecule used to form the Ru film, where the molecular structure significantly changes the thickness required to form a continuous film (refer to Example 1 explained later). This is probably applicable, to some extent, to a case where a Ru film is formed on a pre-treatment layer. However, a Ru film tends to grow easily on a pre-treatment layer than on a conventional metal film, so a Ru material gas can be chosen from a wider selection than the gases available when a Ru is formed on a conventional metal film.

One embodiment of the present invention uses a Ru material gas selected from molecules having a Ru(XaXb) structure, wherein at least one of Xa or Xb is a non-cyclic dienyl. A non-cyclic dienyl (also referred to as “linear dienyl”) may have a 5-member, 6-member, 7-member or 8-member chain, among others, but in one embodiment a 5-member non-cyclic pentadienyl can be used favorably. This non-cyclic dienyl may have a side chain with a carbon number of 1 or above (preferably 2 or less) bonded to it.

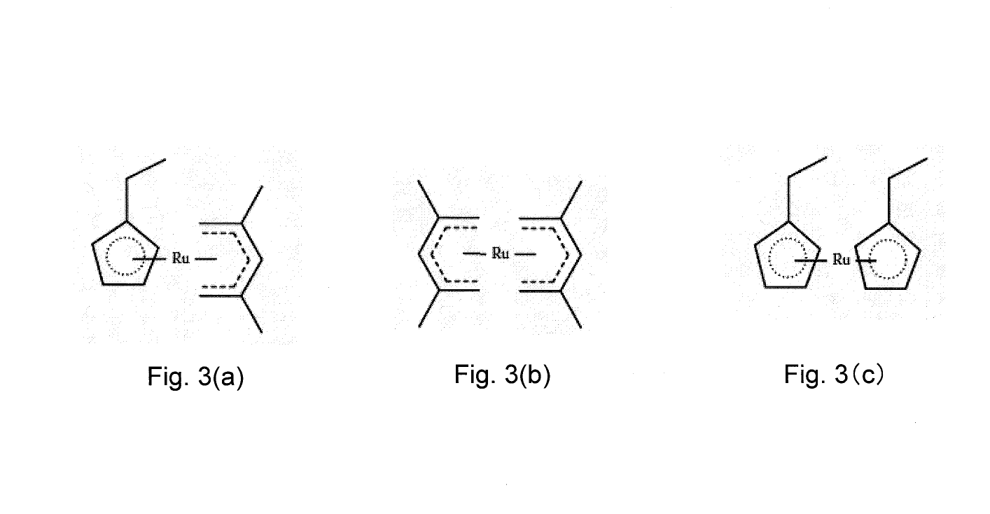

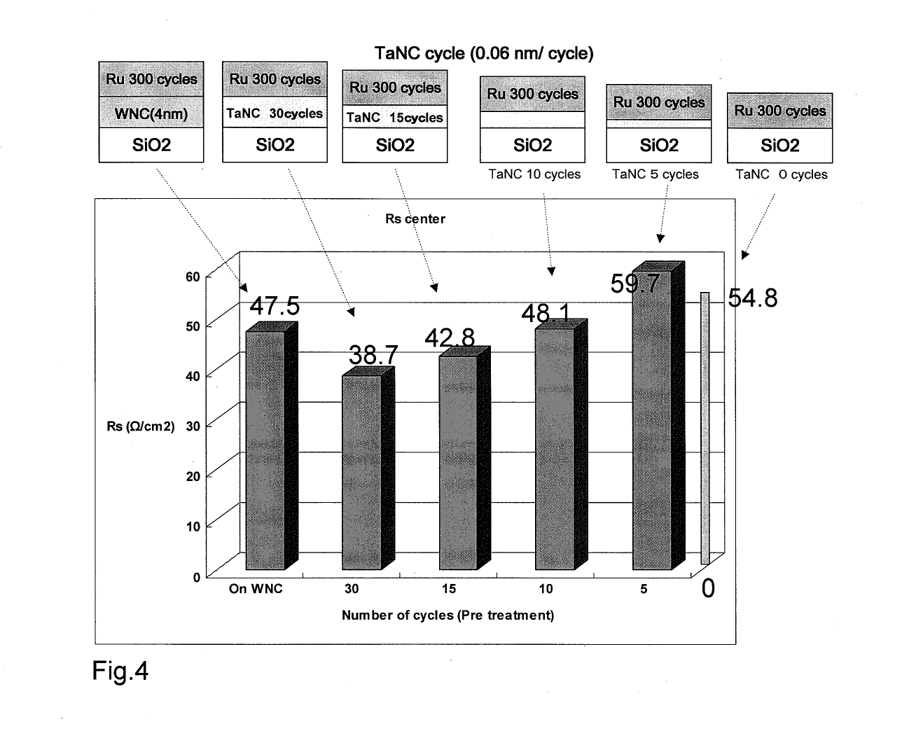

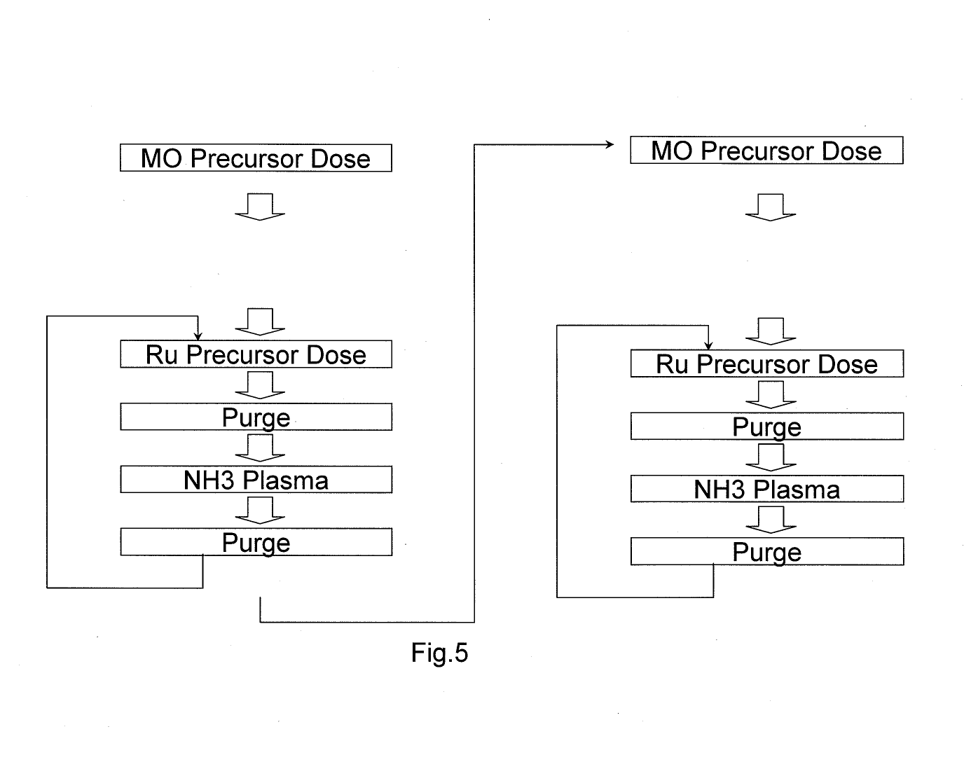

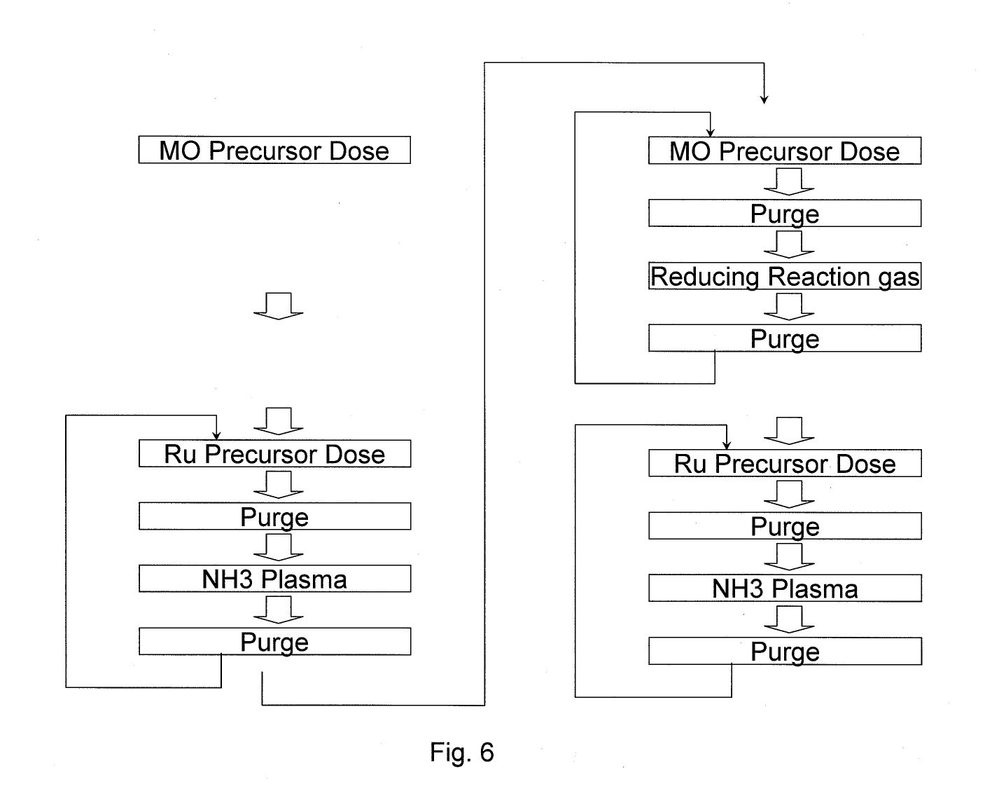

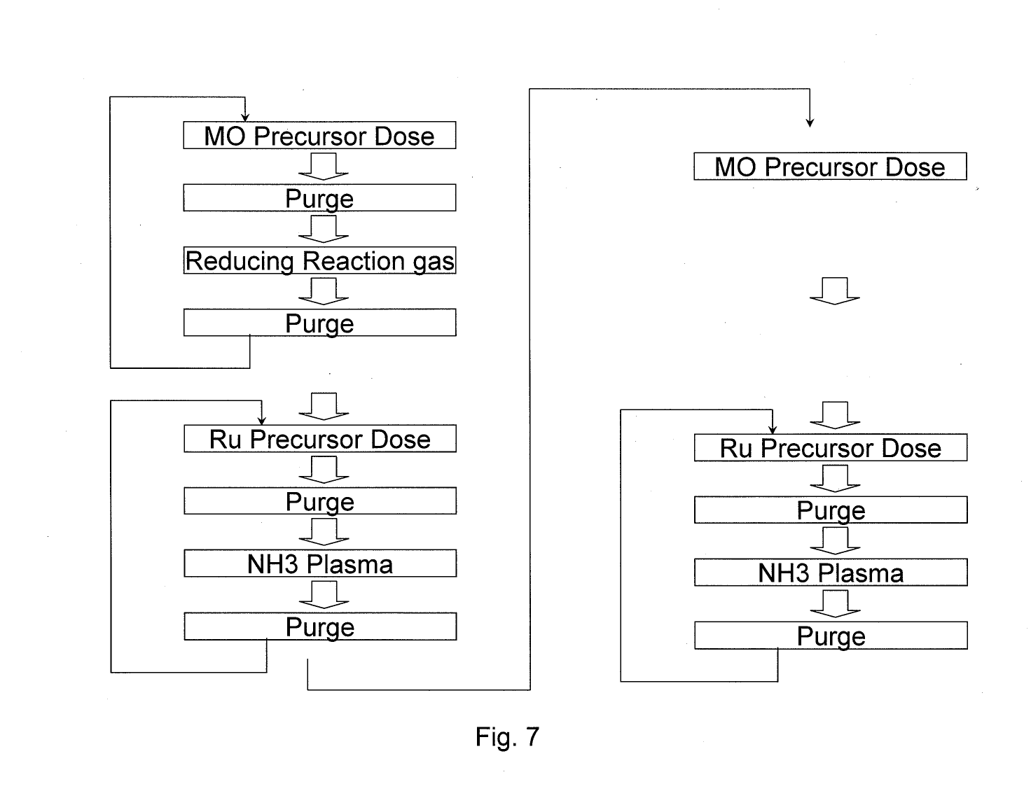

In one embodiment, the aforementioned pentadienyl group in the Ru material having a Ru(XaXb) molecular structure wherein at least one of Xa or Xb is a non-cyclic pentadienyl (also simply referred to as “pentadienyl”) may have a side chain with a carbon number of 1 or above bonded to it. The materials shown in FIGS. 3(a) and (b) both have a two-methyl-group side chain attached to the pentadienyl group. In addition to this side chain, the ethyl or butyl group may also be bonded, for example. Preferably, any hydrocarbon side chain bonded to the pentadienyl group should have a carbon number of 2 or less. Also, the number of bonded side chains should be 1 to 4, or preferably 2 or less. A pentadienyl group structure without side chain is also acceptable.

In one embodiment, the pentadienyl is either 1,3-pentadienyl or 1,4-pentadienyl.

In US2006/0177601A1, the structure is limited to one having a cyclopentadienyl group only, and use of any other Ru compound is prohibited. This is because the cyclopentadienyl group is chemically very stable and easy to handle. Although it is difficult to form a continuous Ru film with a very small thickness in some cases (such as when a Ru film is formed on a WNC film) using a Ru material having a cyclic cyclopentadienyl (such as cyclopentadienyl (Cp), methylcyclopentadienyl (MeCp), ethylcyclopentadienyl (EtCp) or isopropylcyclopentadienyl (i-PrCp)). In one embodiment, however, such cyclic complexes can also be used. When a Ru compound having a non-cyclic dienyl group is used, a very thin (1 nm or less) but continuous film can be formed. Combining a Ru material with reducing NH3 plasma allows for formation of a dramatically thin continuous film. For example, while using a Ru material having a cyclopentadienyl only requires a thickness of 3 to 4 nm on a metal film in order to form a continuous film, use of a Ru material having a pentadienyl forms a continuous film with a thickness of only around 0.6 nm on a metal film. This technology to form a continuous thin Ru film has significant impact on resistance reduction and reliability improvement of wiring to help create finer copper wiring for future semiconductor devices, and combination of the aforementioned material with NH3 plasma allows for dramatic quality improvement of semiconductor devices. Cyclopentadienyl complexes are easy to synthesize, and thus affordable, and they are also structurally stable. These features make cyclopentadienyl complexes suitable for industrial production applications. Although they can form a favorable ALD (atomic layer deposition) film, problems occur if the film thickness is reduced further.

FIG. 3(a) shows one example of a Ru precursor that can be used in one embodiment. This precursor has one pentadienyl group and one cyclopentadienyl group attached to Ru. In FIG. 3(b), two pentadienyl groups are attached to Ru. Using these Ru precursors, a thin but continuous film can be formed easily by, for example, repeating the Ru-material supply step and NH3-plasma treatment step shown in FIGS. 2(a) and (b). If the Ru precursor having two cyclopentadienyl groups attached to Ru, as shown in FIG. 3(c), is used, on the other hand, formation of a continuous film requires a thicker film than when the Ru precursors in FIGS. 3(a) and (b) are used. It is assumed that this is because with the Ru precursors shown in FIGS. 3(a) and (b), the adsorbed pentadienyl group of the Ru material easily becomes unstable on the substrate surface and promotes adsorption of the Ru material molecule. In the next NH3-plasma treatment step, the pentadienyl group detaches easily, and in the case of the Ru precursor in FIG. 3(b) the other group attached to the Ru material also becomes unstable and detaches. On the other hand, the Ru material having two cyclopentadienyl groups remains stable on the substrate and thus the pentadienyl groups detach slowly from the Ru material even when NH3 plasma is introduced in the next step. This creates areas where the pentadienyl group is partially absorbed, detached or not yet detached, which ultimately makes it difficult for a smooth Ru film to form. Therefore, it was found that a continuous Ru film with a thickness of only approx. 1 nm could be formed by repeating a step of introducing a Ru material molecule having at least one pentadienyl group, and a NH3 or H2-plasma treatment step. With the precursor shown in FIG. 3(c), it was difficult to form a continuous film unless the thickness was 3 nm to 4 nm. However, it is possible to form a continuous thin Ru film even with a cyclic Ru complex, if the pre-treatment layer proposed in one embodiment of the present invention is used.

Next, in one embodiment of the present invention a Ru material gas different from the aforementioned Ru material gas can be supplied simultaneously onto a substrate. This different material may have the Ru precursor shown in FIG. 3(c) (i.e., (Ru(EtCp)2) mixed with it. The mixing ratio should be such that the different material accounts for approx. 50 to 95% (by flow rate). In other words, in one embodiment a Ru complex containing at least one non-cyclic dienyl group may be used for 5% or more (including 10%, 30%, 50%, 80%, 100% and other percentages in between), with a different material (particularly a Ru complex containing only a cyclic dienyl group) accounting for the remainder. For example, the different material may be used for 50% or more. One advantage of supplying different materials simultaneously is that while a material containing a pentadienyl group can be easily broken down with NH3 plasma to form a Ru core, once a Ru core has been formed the adsorption of Ru(EtCp)2 is promoted and thus Ru formation can be promoted with the different material alone. There is also an economic advantage, in that the use of Ru(EtCp)2 that can be produced inexpensively allows for formation of a Ru film at lower cost.

In one embodiment, a step of supplying the aforementioned Ru material gas (one cycle of this step consists of supply of the Ru material, purge, NH3 plasma treatment, and purge) is repeated for a specified number of cycles (such as 10 cycles, 20 cycles, 30 cycles, 40 cycles, 50 cycles and other cycles in between), after which a step of supplying a different Ru material gas (such as a Ru complex containing only a cyclic dienyl group like Ru(EtCp)2) (one cycle of this step consists of supply of the different Ru material, purge, NH3 plasma treatment, and purge) is repeated for a specified number of cycles (such as the remaining 90 cycles, 80 cycles, 70 cycles, 60 cycles, 50 cycles and other cycles in between, if a total of 100 cycles are to be repeated together with the preceding step). In this case, advantages similar to those described above can also be achieved.

In one embodiment, a Ru film or Ru oxide film may be layered over the aforementioned Ru film already formed, via chemical vapor deposition (CVD) using an arbitrary Ru material and oxygen gas. Whether a Ru film or Ru oxide film is formed by CVD depends on the partial pressure of oxygen, where a low partial oxygen pressure forms a Ru film, while a high partial oxygen pressure forms a RuOx film. Here, either a Ru film or RuOx film may be formed in accordance with the purpose. However, the underlying barrier film is not oxidized due to the presence underneath of the Ru film formed by plasma ALD. One drawback of plasma atomic layer deposition, or atomic layer deposition, is that a slow growth process reduces productivity when a thick film is formed. On the other hand, chemical vapor deposition promotes quick growth and therefore permits formation of a thick film over a short period of time. In other words, a Ru film can be formed efficiently by forming an underlying Ru film of approx. 1 to 2 nm via plasma ALD, and then forming a thicker film in a chemical vapor deposition process. For example, it would be effective to form a Ru film or RuOx film of approx. 10 to 20 nm by CVD. Although the film growth speed with CVD is 10 to 100 times the film growth speed attained with ALD, CVD needs oxygen gas and also requires an ALD Ru film to be formed underneath using a reducing gas.

In one embodiment of the aforementioned CVD, oxygen gas is supplied at a flow rate of 20 to 100 sccm, a Ru material is heated to a temperature range of 80 to 100° C., and an inactive gas (such as Ar gas) is supplied at a flow rate of approx. 300 to 500 sccm into the reaction apparatus. Ar gas can also be supplied at a flow rate of 900 to 1,200 sccm. The substrate should be kept at a temperature in a range of 300 to 400° C., to form a film under a pressure of 1 to 3 torr.

In one embodiment, a copper film may be formed on the aforementioned Ru film. The copper film can be formed on the aforementioned Ru film by means of a chemical vapor deposition or atomic layer deposition method, by supplying a copper material molecule into vacuum in gaseous form. This copper film can be formed using Cu(hfac)(tmvs) ((trimethylvinylsilyl)(hexafluoroacetylacetonat)) as the material, and by adjusting the substrate temperature to a range of 90 to 200° C. An inactive gas may be introduced as a carrier gas at a flow rate of 300 to 500 sccm. Cu(hfac)(tmvs) should be supplied at a speed of approx. 50 to 200 mg/min. Vaporization can be caused using a general vaporizer at a temperature in a range of 60 to 80° C., and the vaporized copper material is supplied to the reaction apparatus. The film forming pressure should be adjusted to a range of 1 to 2 torr.

As explained above, a continuous Ru film can be formed easily on an insulation film made of SO2, etc., by exposing a metal-organic precursor such as Ta, Ti, Hf, Nb or Zr onto the surface of a oxide film, as shown in FIG. 1(a), before the Ru forming process is performed, or by repeating at least once a step of introducing the above material, and a plasma step using a reducing gas such as NH3 or H2, to form a thin film containing Ta, Ti, Hf, Nb, Zr, etc., as shown in FIG. 1(b). This allows for formation of a continuous Ru film with a thickness of 1 nm or so, which cannot be achieved with the method disclosed in US2006/0177601A. If reducing gas plasma is used to perform at least one cycle in accordance with the plasma atomic layer deposition method to form an ultra-thin metal film containing Ta, Ti, Hf, Zr or Nb, in one embodiment a continuous Ru film with a thickness of 1 nm or more can be formed by repeating one to 30 cycles or so to form an underlying film with a thickness of 0.03 nm to 2 nm, because a TaN, TaNC, TiN or TiNC film grows by approx. 0.03 to 0.06 nm per cycle.

FIG. 4 is an example (Example 3 explained later) showing a notable effect of the present invention in one embodiment, although this example is not intended to limit the present invention in any way. FIG. 4 compares the sheet resistances of films formed respectively with: (1) a method whereby a metal WNC film of 4 nm was formed by ALD, after which the Ru material shown in FIG. 3(a) was used with the NH3 plasma step shown in FIG. 2(a) to repeat 300 cycles in accordance with the atomic layer deposition method to form a Ru film; (2) a method whereby a Ta metal-organic precursor Taimata (Tertiaryamylimidotrid(dimethylamido)tantalum) was introduced to SiO2 in the step shown in FIG. 1(a), after which the same process shown in FIG. 2(a) was repeated for 300 cycles; and (3) a method whereby a Taimata process consisting of the step shown in FIG. 3(b) was repeated for 5, 10, 20 and 30 cycles, respectively, followed by 300 cycles based on the plasma atomic layer deposition method using the step shown in FIG. 2(a).

Although the sheet resistance tends to decrease as the Ru film becomes thicker, the pre-treatment using Taimata alone achieved a Ru film of low sheet resistance. Conventionally, forming a Ru film on SiO2 without providing any pre-treatment does not achieve a continuous film and therefore either resistance cannot be measured or the measured resistance is only around 100 times the level achieved with the pre-treatment. This shows that this Taimata pre-treatment makes it easier for a Ru film to grow. Also, while the sheet resistance decreases as the amount of Taimata and the number of hydrogen plasma cycles increase, the resistance is lower with a Ru film formed on TaNC by means of Taimata and hydrogen plasma, compared to a Ru film formed on a WNC film. This suggests that a Ru film initially grows faster on TaNC than on a WNC film. Since the growth speed per one Taimata and hydrogen plasma cycle is approx. 0.06 nm, the thickness is still approx. 2 nm after 30 cycles, which is less than the WNC film thickness of 4 nm. In other words, the Taimata pre-treatment, and formation of a ultra-thin TaNC film using Taimata, facilitate the formation of Ru film and allow a continuous Ru film to form easily. Since a continuous Ru film is formed, Cu diffusion can be prevented at a thickness of 1 nm or more.

In FIG. 4, the result after five cycles is poorer than the result obtained with metal gas exposure. This is because when a film is formed, it is sometimes formed in an island pattern initially (such as in the first five cycles), in which case the Ru film becomes non-uniform. When TaNC was formed over 10 cycles or only Ta was adsorbed, a film did not form in an island pattern, suggesting that a uniform Ru film was formed (this explanation is not intended to limit the present invention in any way). In other words, it is assumed that at fewer cycles associated with the tendency of a TaNC film to form in an island pattern, the Ru film did not have a sufficient density and thus its resistance increased.

Also in one embodiment of the present invention, Cu diffusion from the grain boundary in the Ru film can be suppressed further by adding Ta, Ti, Zu, Hf, Nb or Al to the Ru film. In this case, a Ru film is formed on a very thin metal film or after a metal-organic precursor treatment is performed, in order to use the Ru film as a barrier film, which is effective in reducing the battier film thickness and wiring resistance. Also, good adhesion with Cu can be achieved, which has the effect of enhancing wiring reliability. As for the method to introduce an additive, the methods shown in FIGS. 5 through 8 can be used, for example. Even when no additive is introduced, forming a Ru film after forming a Ta or Ti film should promote the diffusion of Ta or Ti at the crystal grain boundary in the Ru film and thereby provide the effect of preventing Cu diffusion through the Ru grain boundary under NH3 plasma. If the Ta or Ti element does not fully diffuse in the Ru film, on the other hand, adding a step of supplying more Ta or Ti atoms during the formation of Ru film can enhance the function of the Ru film as a Cu diffusion barrier, because Ta or Ti element as well as TaN or TiN products are formed at the crystal grain boundary of Ru.

However, the resistance of a Ru film is lower than that of a Ta or Ti film by at least one digit, and therefore an increase in the Ta or Ti content results in a higher resistance. For this reason, introduction of Ta, Ti, etc., to the Ru film should be examined in accordance with the purpose, from the viewpoints of both resistance and Cu diffusion barrier. If Ta or Ti is introduced, the embodiments shown in FIGS. 5 through 8 can be used. Formation of a Ru film and introduction of Ta or Ti can be performed in the same module, or in different modules.

As shown in FIG. 5, a treatment step using a metal-organic precursor such as Ta or Ti is added between the Ru formation cycles, so that a Ru film is formed after a treatment with a metal-organic precursor such as Ta or Ti. Also as shown in FIG. 6, a treatment step using a metal-organic precursor such as Ta or Ti is added, along with a step of forming a Ru film and then form TaN, TaNC, TiN or TiNC for at least one cycle using a metal-organic precursor such as Ta or Ti, after which a Ru film is formed again. Alternatively as shown in FIG. 7, TaN, TaNC, TiN, or TiNC is formed for at least one cycle using a metal-organic precursor such as Ta or Ti, after which a Ru film is formed by the atomic layer deposition method, and then a step of introducing a metal-organic precursor such as Ta or Ti is provided, followed by formation of a Ru film again. Another way is to, as shown in FIG. 8, perform a step of forming TaN, TaNC, TiN or TiNC for at least one cycle using a metal-organic precursor such as Ta or Ti, after which a Ru film is formed by the atomic layer deposition method, and then TaN, TaNC, TiN, or TiNC is formed for at least one cycle using a metal-organic precursor such as Ta or Ti, followed by formation of a Ru film.

In the above methods, the number of cycles should be anywhere from one to 30, or preferably five to 20 or so (similar numbers of cycles used for the pre-treatment layer can be applied). In one embodiment, the thickness of a Ru film containing an additive may be the same as the thickness of a Ru film not containing any additive. If an ALD film formed using a metal-organic precursor is sandwiched between Ru films, the upper Ru film and lower Ru film may have an equivalent thickness or different thicknesses. In one embodiment, the thickness of the lower Ru film and that of the upper Ru film are 0.5 nm or more, respectively, with the total film thickness amounting to approx. 1 to 3 nm.

Such a layered structure may be constituted not only by one layer, but also by two, three or more layers. In one embodiment, Ru formation can be repeated for one or more cycles after one Ta/Ti cycle, and then this sequence is repeated several times to produce a layered film constituted by alternating layers of Ta or Ti and Ru. In FIGS. 5 through 8, however, the surface of the composite film needs to be covered with a Ru film. This is to improve the adhesion with Cu. On the other hand, providing a step of introducing a metal-organic precursor during the formation of Ru film for improving the barrier property has the effect of producing a nitride of atoms of the metal-organic precursor at the grain boundary of the Ru film to prevent diffusion of Cu.

In the present disclosure where conditions and/or structures are not specified, the skilled artisan in the art can readily provide such conditions and/or structures, in view of the present disclosure, as a matter of routine experimentation. For the purposes, the disclosure of U.S. Publication No. 2006/0177601A1 is incorporated herein by reference in its entirety. Also, the disclosure of U.S. patent application Ser. No. 11/367,177 and Ser. No. 11/469,828 owned by the same assignee as in the present application is incorporated herein by reference in its entirety.

The present invention will be explained in detail with reference to the drawings. However, the drawings are not intended to limit the present invention.

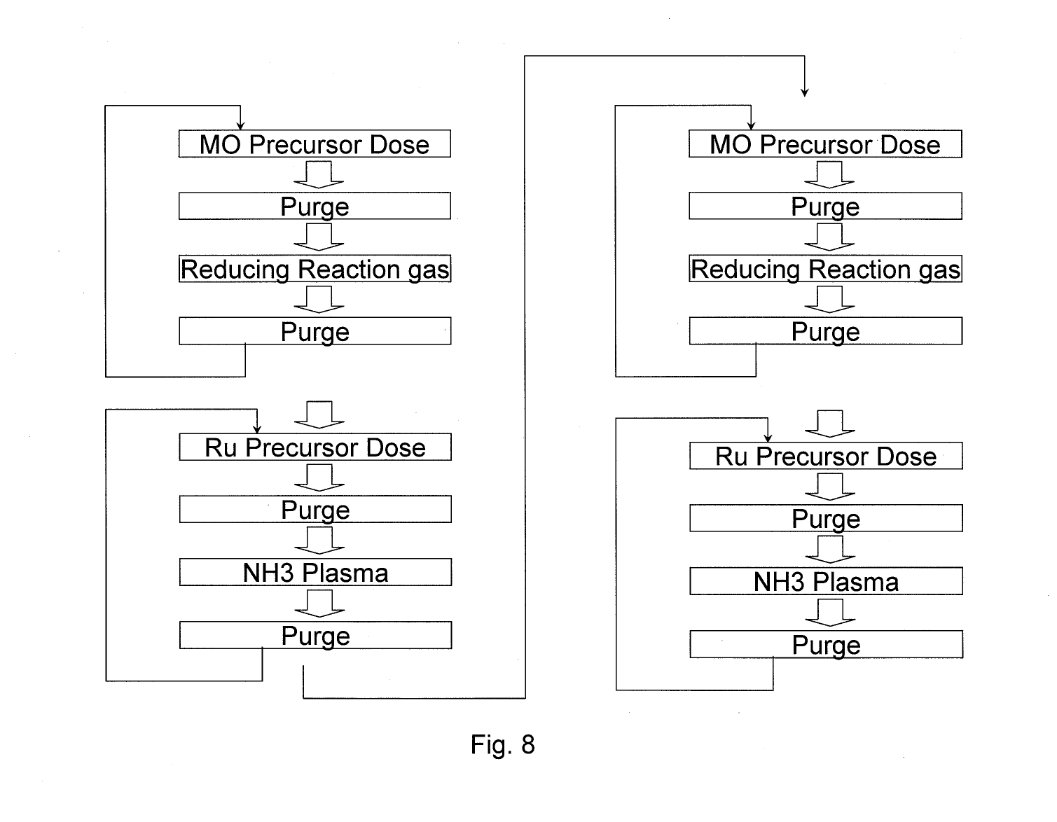

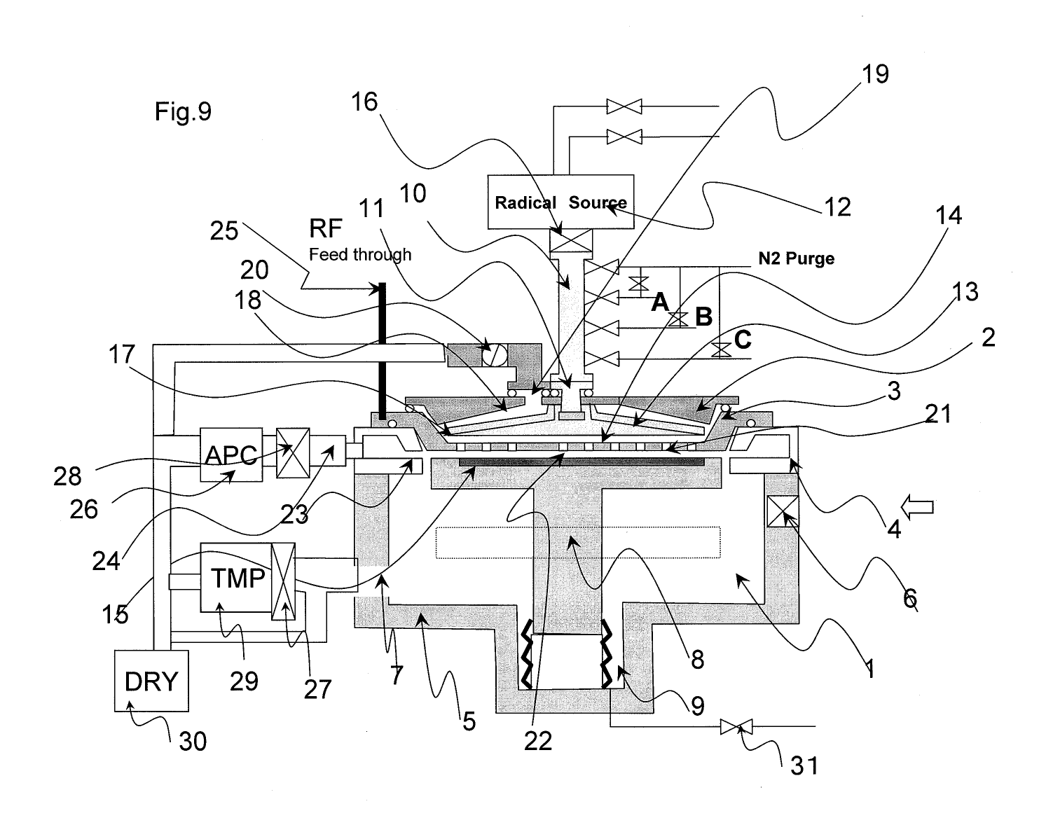

FIG. 9 shows one example of a thin-film forming apparatus that can be used to implement the present invention. This thin-film forming apparatus allows a semiconductor substrate, which is a processing target, to be transferred to a reaction chamber 1 from a vacuum transfer chamber (not illustrated), and a thin-film forming process can be implemented in this reaction chamber 1. This reaction chamber comprises an upper lid 2, dispersion plate 3, exhaust duct 4, lower chamber 5, substrate transfer gate 6, exhaust port 7, substrate heater 8, and substrate-heater up/down bellows 9. After having been introduced into the reaction chamber 1, the semiconductor substrate is placed on the substrate heater and the substrate heater can be moved upward to obtain an optimal distance between the dispersion plate 3 and the substrate.

Also, the upper lid is connected to a gas introduction piping 10 and gas introduction part 11. A reactive gas is connected to the piping 10, and a nitrogen gas or inactive gas for purging the reactive gas is also connected. The piping 10 is also connected to a radical source 12 via the gate valve 11, and various types of radical gases generated in the radical source 12 can be introduced by opening the gate valve 11. The gas introduction part 11 connects to a gas dispersion part 13, and the gas introduced from the gas introduction part diffuses and disperses in the gas dispersion part 13. The gas introduction part 11 may also have a diffusion structure that allows a gas to be introduced in a dispersed manner into the gas dispersion part 13. The gas diffused in the dispersion part 13 reaches a space 14 between the dispersion part 13 and the dispersion plate 3. A slit-type exhaust port 17 is formed between the tip of the gas dispersion part 13 and the dispersion plate 3, and this slit is provided in a circular form at the tip of the dispersion part 13. Numeral 18 is a space continuing to this exhaust slit 17, and this space 18 is formed by the outer wall of the dispersion part 13 and the upper lid 2, and continues to the space surrounding the gas introduction part 11.

Formed on the upper lid is a flange connection port for exhaust 19 that continues to this space 18, and also to an exhaust valve 20. On the other hand, the gas that has passed the gas dispersion part 13, the space 14, and a gas discharge port 21 provided on the dispersion plate 2 to finally reach a space 22 between the substrate-heating table 8 and the dispersion plate 2, further travels to reach the surface of a substrate 15, and then is discharged through a ring slit 23 formed in the exhaust duct 4 and out of an exhaust pipe 24 continuing from the slit. High-frequency electrodes are introduced to the dispersion plate 2 through 25 to generate plasma between the dispersion plate 2 and the substrate-heating table 8.

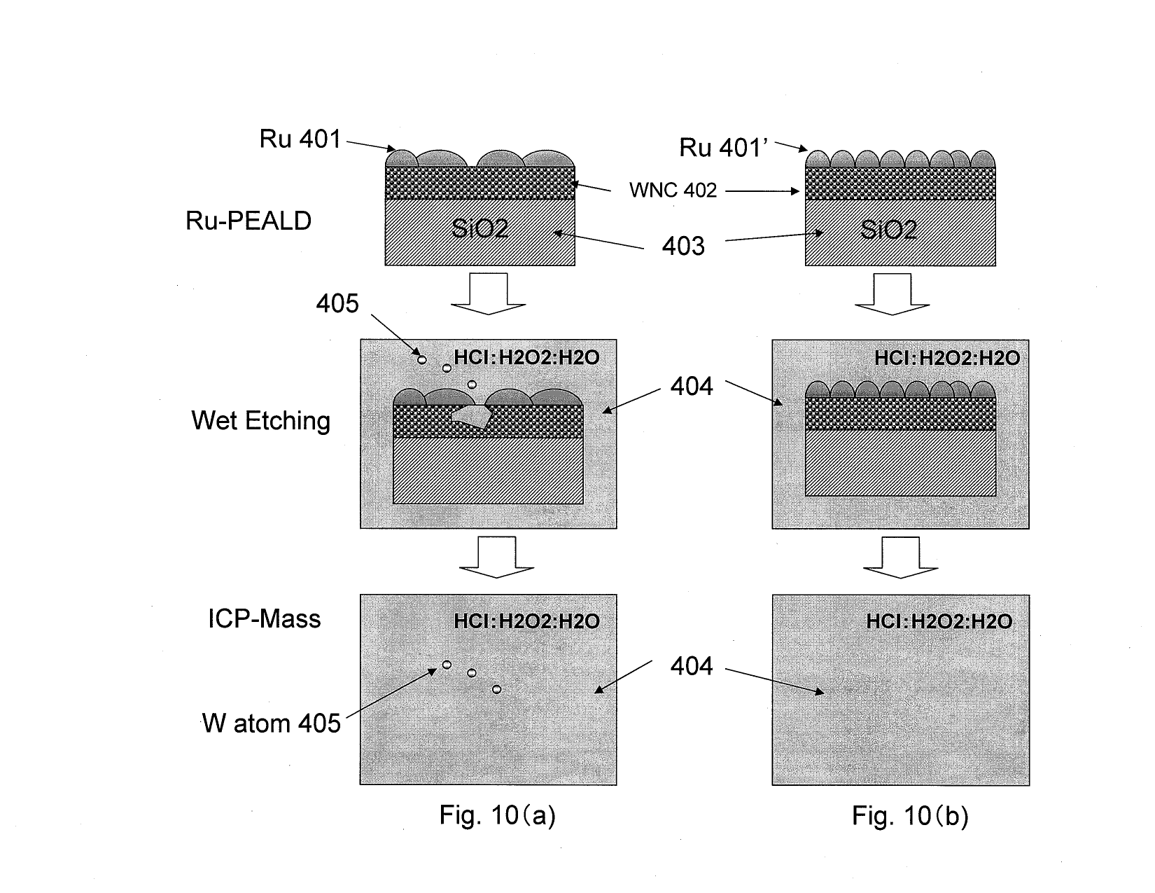

FIGS. 10(a) and (b) show how to evaluate the continuity of a Ru film. FIG. 10(a) applies to a case where the Ru film is non-continuous, while FIG. 10(b) applies to a case where the Ru film is continuous. A WNC film 402 is formed on a SiO2 film 403, and then a Ru film 401 or 401′ is formed, after which the obtained sample is soaked in a wet-etching solution 404 (a mixed acid consisting of hydrochloric acid and hydrogen peroxide) that can dissolve the WNC film, to measure and quantify via ICP mass spectrometry the amount of tungsten (W) 405 eluted from the WNC film into the wet-etching solution. The schematic diagram in (a) shows a condition of how the WNC film is etched by pinholes when the Ru film 401 is not continuous. In (b), the Ru film 401′ is continuous if the core density is high, in which case the wet-etching solution cannot reach the WNC film and thus no tungsten atoms eluted from the WNC film are detected in the etching solution. While wet-etching solution is a mixed acid consisting of HCL, H2O2 and H2O mixed at 1:1:20 that etches WNC films to cause elution, this solution does not etch Ru films. Therefore, if the Ru film is not continuous, the underlying WNC film is etched and its constituents are eluted. Accordingly, the amount of W can be detected by measuring the etching solution via ICP mass spectrometry.

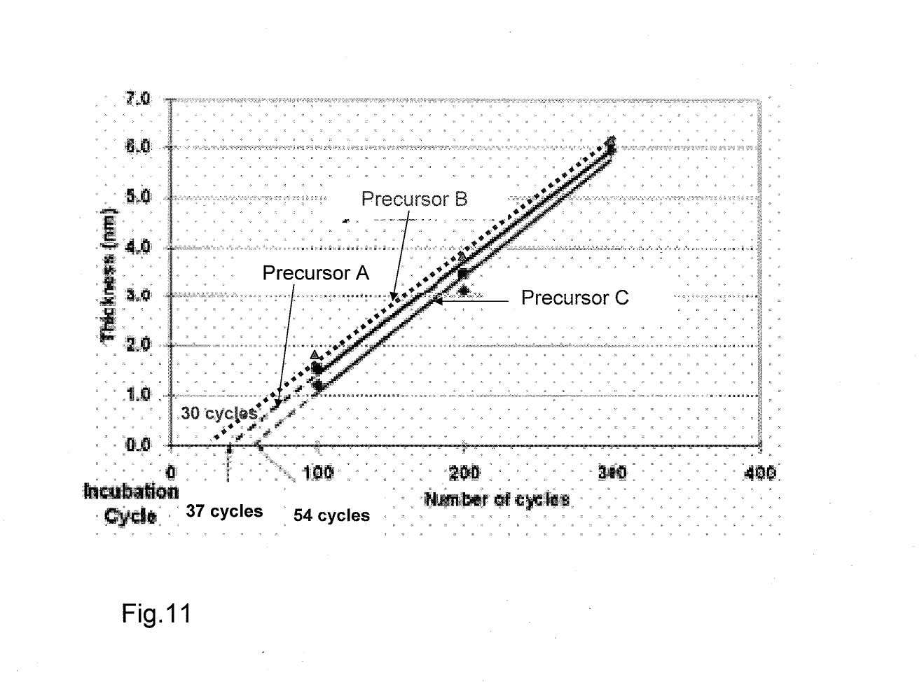

FIG. 11 shows the dependence of Ru growth speed on number of cycles when the Ru material shown in FIG. 3(a), (b) or (c) was used. The film forming conditions are explained in Example 2 later. As for the number of cycles, the step shown in Table 2 under Example 2 was defined as constituting one cycle, and how many times this cycle is repeated was counted. The incubation cycles (corresponding to the thickness zero point obtained by extrapolating the proportional relationship of thickness and number of cycles) for the Ru materials in FIGS. 3(a), (b) and (c) were 37 cycles, 30 cycles and 54 cycles, respectively.

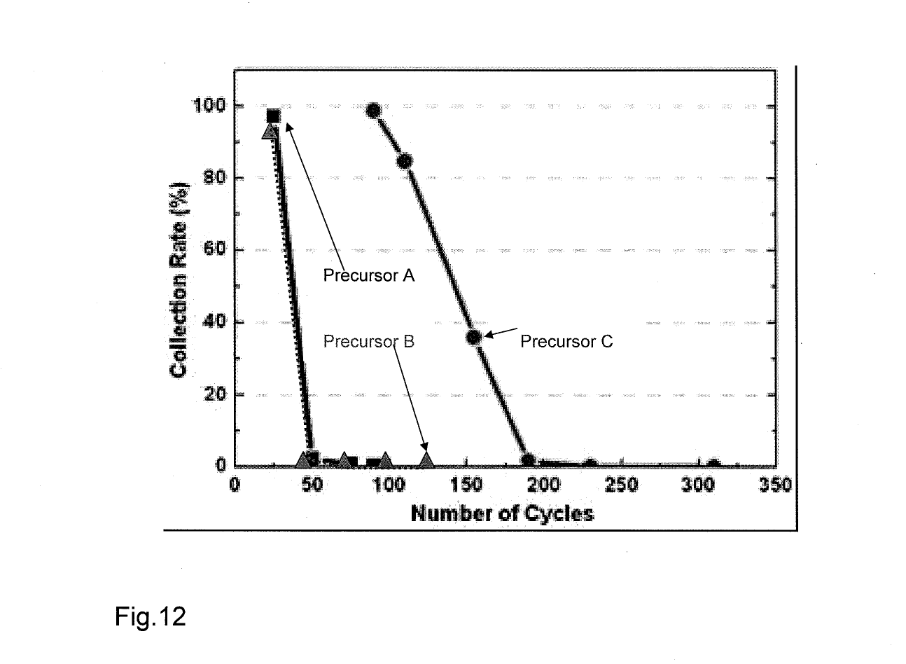

FIG. 12 shows the relationship of the number of cycles for the Ru film formed in FIG. 11, and the detected amount of W, as obtained using the method illustrated in FIG. 10. Here, the collection rate indicates the percentage of the actual amount of W atoms detected, to the total W atoms in the WNC film beneath the Ru film by assuming that all W atoms have eluted into the etching solution. “100%” indicates that all were etched, while “1%” indicates that an amount of W corresponding to 1% of total W atoms has been detected. With the Ru precursors in FIGS. 3(a) and (b), a nearly perfect continuous film was formed after 50 cycles. With the Ru precursor in FIG. 3(c), on the other hand, a continuous film was not formed for 200 cycles.

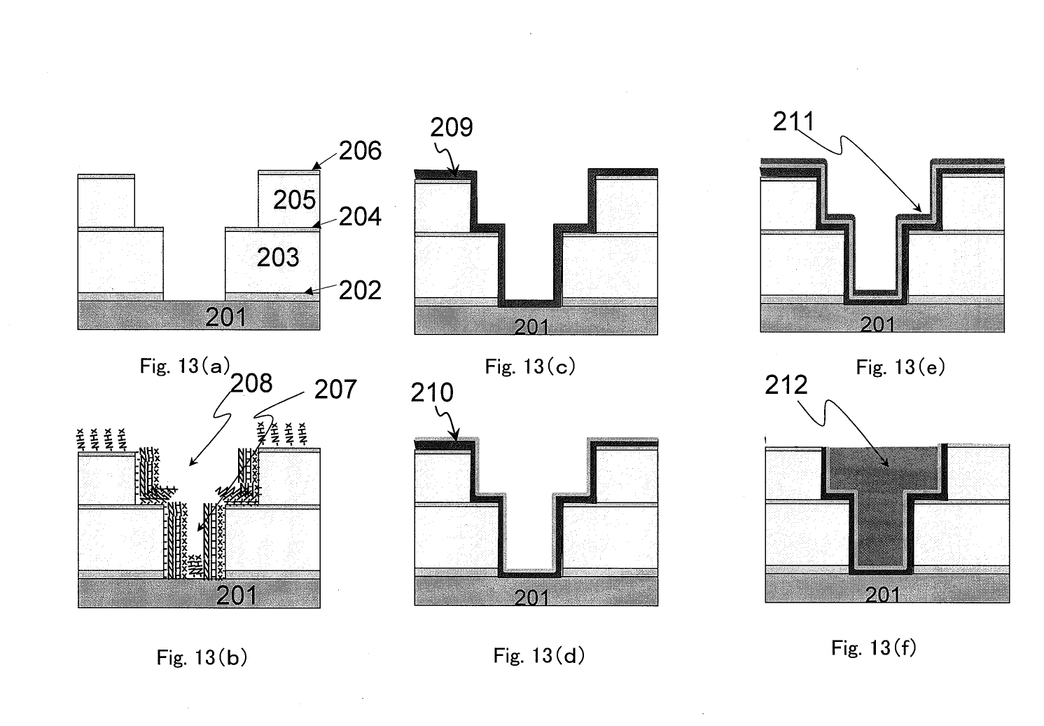

FIG. 13 shows a process flow where the aforementioned process is applied to a dual-damascene Cu wiring process.

FIGS. 13(a) through 13(d) are schematic cross-section drawings showing a wiring structure of a semiconductor element, presented to explain a process of forming a dual-damascene copper wiring structure conforming to one embodiment of the present invention. Specifically, these diagrams explain a process of lining the entire surface of trenches and contact vias in a dual damascene structure with a metal barrier film using the ALD method, followed by the formation of a Ru film and a copper layer.

FIG. 13(a) illustrates a dual damascene structure prior to the formation of metal barrier layer. A dielectric diffusion barrier 202 is formed on a conductive wiring layer 201, and a bottom insulation layer 203 is formed on top of the dielectric diffusion barrier 202, while an etching stop layer 204 is formed on the bottom insulation layer 203. A top insulation layer 205 is formed on top of the etching stop layer 204. The etching stop layer 204 is used to form trenches 208 of a desired wiring pattern. The trenches 208 are etched on an etching mask layer level, and formed between two insulation layers 205, 203. The etching stop layer 204 is patterned and etched prior to the formation of the top insulation layer 205, and constitutes a hard mask that clearly defines a desired horizontal dimension of contact vias extending from the bottom of trenches 208. In the area where the etching stop layer 204 comprising hard mask is etched off, contact vias 207 connecting from the bottom of trenches 208 to the lower conductive wiring layer 201 are opened. Numeral 206 indicates a layer where chemical mechanical polishing is stopped in the smoothing step.

FIG. 13(b) illustrates the pre-treatment process in one embodiment of the present invention. This process comprises removing the oxide formed on the copper wiring surface at the bottom of contact vias 207, and pre-treating the surface of interlayer insulation films 203, 205 exposed in the damascene structure (for example, by introducing H2/He gas for 30 seconds at a RF output of 800 W, and then introducing H2/H2/N2 mixture gas for 60 seconds at a RF output of 300 W). This terminates the surface of interlayer insulation films in the damascene structure with —NH and —NH2 bonds. This termination is difficult to achieve only through simple heat treatment using NH3 gas. When NH3 is activated using high-frequency waves, however, the surface can be terminated using NH and NH2 bonds just like when plasma-activated H2/H2/N2 mixture gas is used.

As for the amino groups to be introduced to the surface of SiO2, SiOC or SiO, etc., if the coordination number of N with respect to atoms on the surface is 1, N, which is a three-coordinate atom, bonds with an atom on the surface and a —NH2 terminal is formed on the surface. If the coordination number is 2, a >NH terminal is formed on the surface. In other words, the surface terminal structure desirable in one embodiment of the present invention is —NH2 or >NH. As explained below, TEB gas and other reducing gases are considered to be adsorbed in the form of substitution with H in this —NH2 bond or >NH bond as shown in FIG. 4, and therefore the presence of —NH2 or >NH is required on the surface. >NH occurs in the case of Si—NH—Si or SiONHOSi, for example. In FIG. 13(b), “x” in —NHx represents 1 or 2.

In an embodiment, introduction of amino groups to the surface occurs not only on the surface of low dielectric constant film, but also on the surface of metal wiring layer at the bottom of vias, as shown in FIG. 13(b).

If a SiOC low dielectric constant film, which is to be used widely on next-generation devices, is adopted as the insulation films 205, 203 shown in FIG. 13(a), the carbon-containing side chains in the SiOC film, such as chains of methyl groups which are alkyl groups, are etched by high-frequency plasma with NH3 gas and consequently CH3, C2H5 and other alkyl groups in the SiOC film are lost. This sometimes causes the contact vias 207 to deform into a barrel shape. If damage to insulation films 205, 203 by high-frequency plasma is suspected, using high-frequency plasma with H2/He/N2 gas can reduce the negative effect on the SiOC film. In one embodiment, the partial pressure of nitrogen in H2/He/N2 is 5 to 50%, or more preferably 10 to 30%. As for the RF output frequency, it can be adjusted to 13.56 MHz (normally 2 MHz or above, but not exceeding 60 MHz). In addition to He, Ar and other inactive gases can also be used. In one embodiment, the process conditions may be set as follows:

In the above explanation, “plasma” refers to so-called parallel-plate plasma generated by high-frequency RF waves of 13.56 kHz, for example, applied between a showerhead and a heating stage on which a substrate is placed. In other words, a substrate is present in a plasma generation atmosphere. Therefore, this process is affected by active species with short life that are generated in plasma, such as ionic active species. Meanwhile, there is a method whereby plasma is generated in a place away from a substrate (using a remote plasma apparatus), and among the activated molecules the neutral molecules with long life are transported to the substrate and used in the surface treatment. This is called radical process. In other words, “radicals” refer to molecules in an electron-excited state compared to a normal (ground) state where electrons are stable. Although radicals are not ionic, they are activated and reactive. In one embodiment of the present invention, plasma and radical can be used interchangeably. Those skilled in the art should be able to determine appropriate radical generation conditions from the corresponding plasma generation conditions.

In the process explained above, amino groups are introduced to the surface via plasma. It is difficult to thermally introduce amino groups without using plasma. For example, introduction of amino groups is difficult to achieve only via supply of NH3. However, introduction of amino groups to the surface is possible without using plasma, if N2H2 gas (hydrazine), etc., is used. In one embodiment, the process conditions using hydrazine may be set as follows. The partial pressure of hydrazine with respect to the total flow rate is preferably between 10 and 50%.

In the step indicated by FIG. 13(c), TEB (triethyl boron) gas or other reducing gas is introduced and then purged with inactive gas, after which WF6 gas or other metal halide is introduced and then purged with inactive gas, after which NH3 gas or other halogen-substituting nitride gas is introduced and then purged with inactive gas. By repeating these introductions and purges, a smooth WNC film or other barrier film containing metal atoms (also called metal barrier film) 209 can be formed on the surface of a damascene structure. Barrier film is sometimes referred to as conductive film, but use of this term is limited to situations where difference from insulation films is emphasized. Barrier films are not always electrically conductive.

As for the reducing gas, B2H6, alkyl boron compound, SiH4, Si2H6 or alkyl silicon compound can be used instead of TEB. As for the metal halide, TaF6 or TiCl4 can be used instead of WF6. As a result, the barrier film containing metal atoms can be formed as a TaN, TaCN, WN, TiN or TiCN film instead of WNC film.

As mentioned earlier, the surface on which the above barrier film is formed is terminated with amino groups. By repeating the process of introducing reducing gas, metal halide, and then halogen-substituting nitride gas, a smooth, uniform barrier film can be formed. U.S. Pat. No. 6,759,325 discloses a method to cause WF6 to be adsorbed to the interior surface of trenches and vias that form a damascene wiring structure, and then reduce the surface using TEB or other reducing gas. However, introduction of a metal halide precursor may damage the interlayer insulation film or cause permeation into the film.

In an embodiment, the barrier film thickness is adjusted to a range of 1 to 5 nm, or preferably to a range of 2 to 4 nm.

In the step illustrated by FIG. 13(d), a second metal film 210, such as Ru film, is formed on top of the barrier film 209, such as a WNC film, using plasma ALD or other method. Here, the second metal film is formed on top of the metal barrier film that has been formed after pre-treatment. This film comprises Ru, Ta or other material offering good adhesion with the copper film used for wires, and acts as a so-called glue layer or adhesive layer. In other words, this film is sandwiched between the copper wiring and the conductive film functioning as a copper diffusion barrier and improves the adhesion between the two.

Ru-ALD can be formed by the plasma ALD method in which the compound described earlier and NH3 plasma are supplied alternately. Since a Ru film is formed in a reducing atmosphere, a laminated structure can be created without oxidizing the WNC film 209.

In an embodiment, the thickness of the second metal film is adjusted to a range of 1 to 10 nm, or preferably to a range of 1 to 3 nm.

FIG. 13(e) shows a step of seeding copper 211 to fill the via/trench with copper. In FIG. 7(f), an excess copper layer above the via/trench is removed by CMP, and the surface of the element is further planarized by CMP, so that the WNC film 209 and the Ru film 210 are removed from the top surface, thereby forming an interconnect copper line 212.

In the above, the 1st RF power may have a frequency of 13 MHz to 30 MHz, and the 2nd RF power may have a frequency of 300 kHz to 450 kHz. The 2nd RF power may be lower than the 1st RF power. According to the above conditions, a SiC film having a thickness of about 2 nm to about 10 nm, preferably about 2 nm to about 5 nm can be formed.

Specific examples are explained below by using the aforementioned drawings.

### EXAMPLE 1

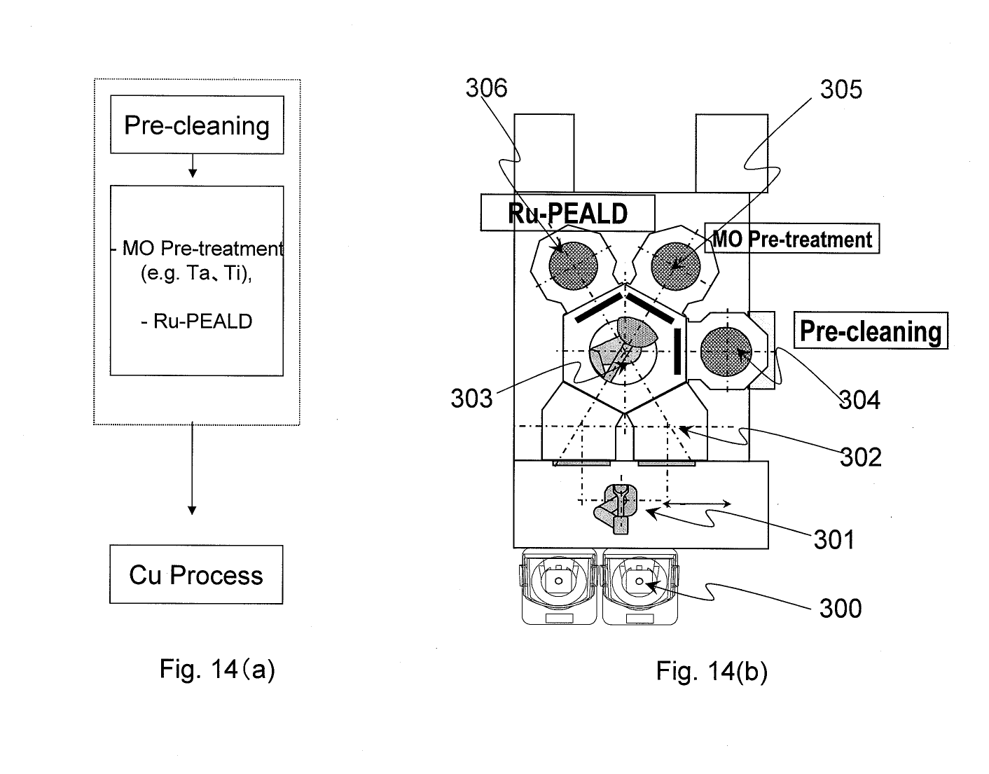

In the process illustrated by the process sequence in FIG. 2(b), that is, the process of forming a metal film and then forming a Ru film using a Ru material based on ammonia plasma ALD, a WNC film formed by ALD was used as the underlying metal film. The WNC film was formed by a process using WF6, NH3 or TEB (triethyl boron) (specifically, the film was formed under the conditions shown in Table 3 using a module 305 in FIG. 14(b) under Example 1 as a WNxCy film forming module). Ru-ALD films were formed using the Ru materials shown in FIGS. 3(a), (b) and (c) as well as the forming apparatus shown in FIG. 9 (under the conditions shown in Table 6 under Example 2). The pre-cleaning (surface treatment) was performed under the conditions shown in Table 4 under Example 2. The results were compared to examine the relationship of pinholes and number of cycles with each film.

TABLE 3

| | | Flow rate | | Pressure | |
|---|---|---|---|---|---|
| Phase | Gas | (Sccm) | Temp. (° C.) | (Pa) | Time (sec) |
| Reduction | TEB | 300 | 350 | 150 | 2 |
| Gas | | | | | |
| Purge | Ar | 2000 | 350 | 150 | 0.5 |
| Metal | WF6 | 300 | 350 | 150 | 0.2 |
| Precursor | | | | | |
| Purge | Ar | 2000 | 350 | 150 | 1 |
| Nitridation | NH3 | 750 | 350 | 150 | 0.5 |
| Gas | | | | | |
| Purge | Ar | 2000 | 350 | 150 | 1 |

FIG. 11 shows the relationship of Ru film thickness and number of cycles. The precursor shown in FIG. 3(c) (hereinafter referred to as “Precursor C”) required 57 cycles, while the precursor shown in FIG. 3(a) (hereinafter referred to as “Precursor A”) required 37 cycles, with the precursor shown in FIG. 3(b) (hereinafter referred to as “Precursor B”) requiring 35 cycles, respectively. FIG. 12 shows the revealed relationship of pinholes and number of cycles with each film. Through quantitative analysis, based on the ICP method, of the amount of tungsten eluted from a unit area of the chip on which a Ru/WNC layered film was formed, using the method illustrated in FIG. 10, the percentage of eluted tungsten to the total tungsten content in the WNC film was measured.

FIG. 12 shows the numbers of cycles corresponding to different collection rates (%) for the Ru materials shown in FIGS. 3(a) and (b). With these Ru materials, the collection rate became 0% at around 50 cycles and 55 cycles or more, respectively. Since tungsten does not elute into the etching solution at a collection rate of 0%, it is determined that continuous films were formed at these cycles. With the Ru material shown in FIG. 3(c), on the other hand, around 200 film forming cycles were needed to achieve a collection rate (%) of roughly 0, at which point tungsten elution is considered none. The sequential process using NH3 plasma as shown in FIG. 2 can form a continuous film over short cycles if a Ru molecule having a pentadienyl group, such as Precursor A or B, is used. With a Ru molecule having only a cyclopentadienyl group, such as Precursor C, however, a continuous film cannot be formed for at least 200 cycles.

As shown in FIG. 11, while the film growth speed per cycle was roughly the same with any Ru molecule, the required incubation time varied among Precursors A, B and C at 37 cycles, 30 cycles and 54 cycles, respectively. When the numbers of cycles at which the formed film was considered uniform were 50, 50 and 200, respectively, the achieved film thicknesses were 0.44 nm, 0.3 nm and 3.4 nm, respectively. Therefore, with the materials shown in FIGS. 3(a) and (b) the film becomes sufficiently continuous if the film thickness is 0.5 nm or more. Also, in practice a semiconductor device has flat sections and stepped sections, and the process using a Ru material with NH3 plasma has been shown to provide a coverage of 70% over holes with an aspect ratio of 5. In other words, a continuous film can be achieved at a thickness of 0.7 nm or more, if device coverage is also considered. In practice, it is preferable to control the film thickness within a range of approx. 0.7 to 1.0 nm. High reliability can also be ensured with a thickness of 1.0 nm or more, because a higher margin can be achieved.

If the Ru material shown in FIG. 3(c) is used, on the other hand, the minimum thickness below which the film no longer became continuous was approx. 3 to 4 nm, which means that a Ru film needs to be 4 nm or thicker in practice. As a result, using this Ru material for actual copper wiring decreases the copper wiring volume by the increased thickness of the Ru film, thus virtually resulting in a higher wiring resistance. To prevent this problem, a thinner Ru film is desired. Since the method proposed by the present invention allows for use of a Ru film of 1 nm or thinner, the copper volume can be increased and wiring resistance decreased, while ensuring good adhesion between the copper wiring and Ru.

With the Ru material having a pentadienyl group, it is considered that the ALD method using NH3 plasma, as explained in this example, allows the Ru component to detach easily by means of NH3 plasma, thus increasing the core formation density and thereby allowing a continuous film to form easily at a small film thickness. If the Ru material only has a cyclopentadienyl, on the other hand, the cyclopentadienyl does not detach easily even under NH3 plasma, and therefore a continuous film does not form easily.

These trends suggest that a thin but continuous Ru film can be formed by using the materials shown in FIGS. 3(a) and (b), even when a WNC film is not used underneath, but a Ru film is formed on a film of TaN, TaNC, TiN, TiNC, etc., or a pre-treatment is provided using a metal-organic precursor such as Ta or Ti instead. In general, a continuous Ru film can be formed with a metal nitride, or with a metal nitrogen carbide containing nitrogen and carbon, in a manner similar to when a WNC film is used.

### EXAMPLE 2

This example shows an application of the present invention to the formation of a wiring process using a dual-damascene structure, which is the most commonly used copper wiring structure, and the effects of such application.

FIG. 13 shows a process to form a dual-damascene structure. FIGS. 13(a) through (f) show a process flow starting from a condition after completion of dual-damascene processing. FIGS. 14(a) and (b) show the structure of the cluster apparatus (FIG. 14(b)) and the cluster process sequence (FIG. 14(a)) used in this example. The cluster apparatus shown in FIG. 14(b) comprises a pre-cleaning module 304, a module for pre-treatment using a Ta metal-organic precursor or for forming TaNC/TaN film 305, and a Ru forming module 306, and performs a process based on continuous vacuum cycles, as shown in FIG. 14(a).

FIG. 13(a) shows a condition after completion of dual-damascene processing. A SiOC film 202, interlayer insulation film 203, etching stopper film 204, interlayer insulation film 205 and copper-diffusion prevention film 206 are formed on a lower-layer copper wiring 201 to produce a copper-diffusion prevention layer. In this condition, surface treatment prior to the formation of ALD barrier film is performed using the surface treatment module 304 shown in FIG. 14(b). The surface treatment conditions are shown in Table 4.

TABLE 4

| | | Flow rate | | Pressure | |
|---|---|---|---|---|---|
| Phase | Gas | (Sccm) | Temp. (° C.) | (Pa) | Time (sec) |
| Pre- | H2/N2 | N2: 100–500, | 100–360 | 300–1000 | 10–60 |
| cleaning | | H2: 10–50 | preferably | Preferably | preferably |
| | | preferably | 150–300 | 200–500 | 20–40 |
| | | N2: 200–300, | | | |
| | | H2: 20–40 | | | |

FIG. 13(b) shows a condition immediately after the surface treatment. Here, a step of reducing the oxide formed on the surface of the copper wiring 203 at the bottom of via contacts 207, is performed simultaneously with a processing to stabilize the surface of the processed end of 202, 203, 204, 205 and 206 constituting the interlayer insulation film over trenches 208 and via contacts 207 in the dual-damascene structure. This processing forms NH or NH2 groups on the surface. After the surface treatment using the surface treatment module 304 shown in FIG. 14(b), the substrate is transferred to the process module for MO pre-treatment 305 as shown in FIG. 14(b), and treated with Taimata which is a metal-organic precursor. Table 5 shows the conditions for Taimata pre-treatment implemented here (the values shown in the table can be modified within a range of ±50%).

TABLE 5

| | | Flow rate | | | Time |
|---|---|---|---|---|---|
| Phase | Gas | (Sccm) | Temp. (° C.) | Pressure (Pa) | (sec) |
| MO precursor | Taimata | 300 | 350 | 150 | 10 |

By this step, Taimata adsorbs to the inner surface of via contacts and trenches, as shown in FIG. 13(c). Adsorption of Taimata is denoted by 209.

Next in FIG. 13(d), a Ru film 210 is formed using the Ru-ALD module 306 shown in FIG. 14(b). Here, the Ru material shown in FIG. 3(a) was used, where the material was treated in a NH3 plasma process conforming to the sequence illustrated in FIG. 2(a). Table 3 shows the Ru-ALD process conditions. Although 700 W was used as the RF power of NH3 plasma, a Ru film can be formed in a RF power range of 200 W to 1,000 W. A similar process can also be achieved at a forming temperature in a range of 250 to 400° C. A Ru film with a thickness of approx. 1 nm was formed over 100 cycles (refer to the conditions shown in Table 6 below; the values shown in the table can be modified within a range of ±50%, and the process can be implemented in a similar manner with other Ru materials).

A Cu seed film 211 shown in FIG. 13(d) is formed on a wafer that has been transferred from the apparatus shown in FIG. 14(b), after which a copper plating film is formed as shown in FIG. 13(e), to form a copper wiring 212 through CMP. A Cu film can also be formed via Cu plating after the Ru film 210 has been formed, or a Cu plating can be formed directly on the Ru film 210. Also, a Cu film may be formed by CVD or ALD instead of using PVD.

As explained above, high reliability can be maintained by continuously performing the series of steps including surface treatment, Taimata pre-treatment, Ru forming via ALD, and Cu plating. The Ru films formed by the aforementioned method exhibited a good copper-diffusion prevention effect even at a thickness of 2 to 4 nm. This is probably because entry of Ta atoms into the crystal grain boundary in the Ru film prevents Cu from diffusing (this explanation is not intended to limit the present invention in any way).

TABLE 6

| | | Flow rate | Temp. | | |
|---|---|---|---|---|---|
| Phase | Gas | (Sccm) | (° C.) | Pressure (Pa) | Time (sec) |
| Ru Dose | Precursor A | 300 | 350 | 150 | 1 |
| Purge | Ar | 2000 | 350 | 150 | 1 |
| NH3 | NH3 | 300 | 350 | 150 | 2 |
| plasma | | | | | |
| Purge | Ar | 2000 | 350 | 150 | 1 |

The above example discussed Taimata, and a TaNC film formed using Taimata. However, the same effect can also be achieved by using Ta(N-t-C4H9)[N(C2H5)2]3, Ta[N(CH3)2]5, Ta[N(C2H5)2]5, Hf[N(CH3)2]4, Hf[N(C2H5)2]4, Ti[N(CH3)2]4, Ti[N(C2H5)2]4, Nb[N(CH3)2]5, Nb[N(C2H5)2]5, Zr[N(CH3)2]4, or Zr[N(C2H5)2]4, instead of Taimata.

### EXAMPLE 3

This example shows an application of the present invention to the formation of a wiring process using a dual-damascene structure, which is the most commonly used copper wiring structure, and the effects of such application.

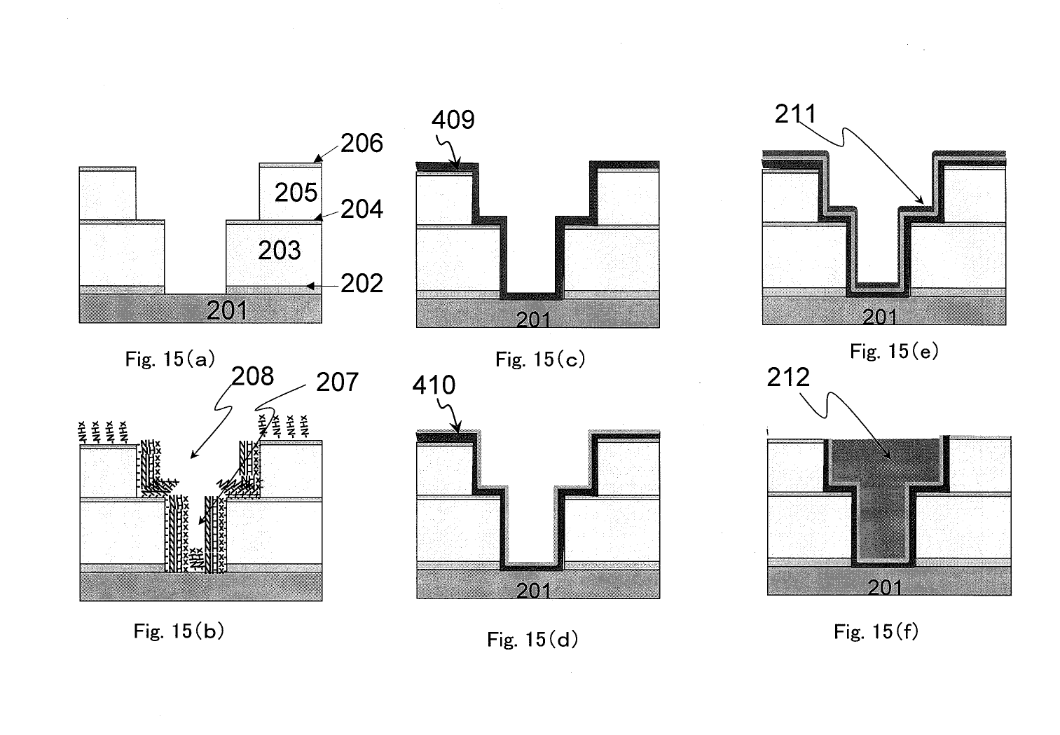

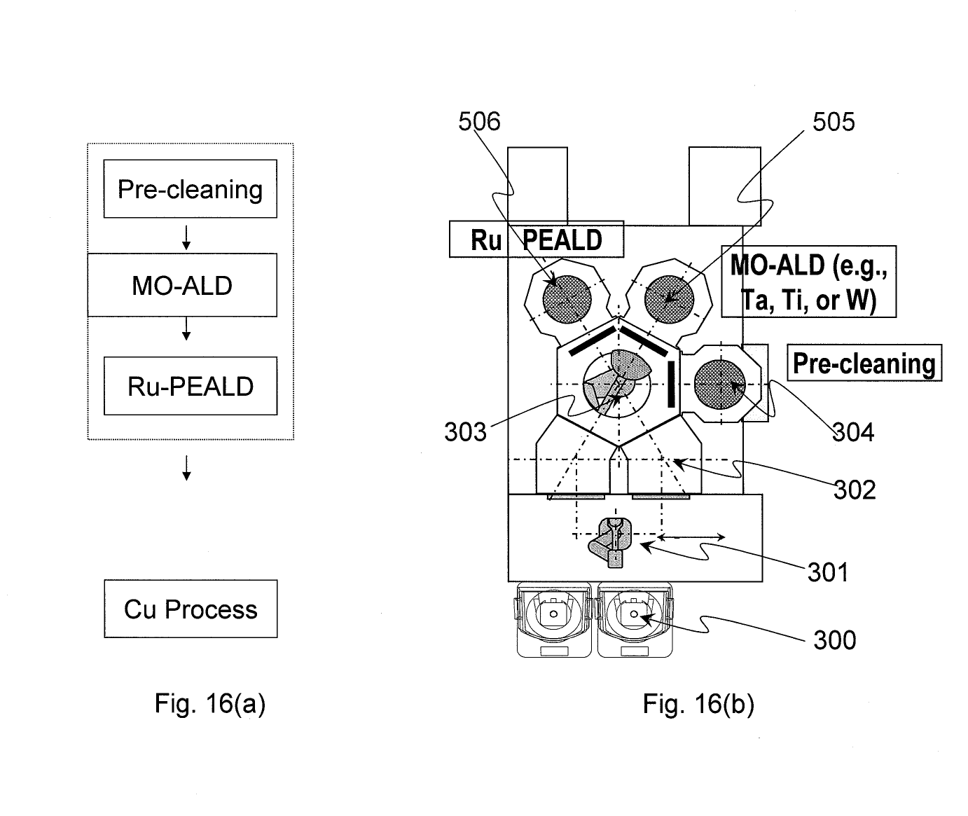

FIG. 15 shows a process to form a dual-damascene structure. FIGS. 15(a) through (f) show a process flow starting from a condition after completion of dual-damascene processing. FIGS. 16(b) and (a) show the structure of the cluster apparatus and the cluster process sequence used in this example, respectively. The cluster apparatus shown in FIG. 16(b) comprises a pre-cleaning module 304, an ALD module for metal film formation using a metal-organic precursor such as Ta, Ti or W 505, and a Ru forming module 506. As shown in FIG. 16(a), a process based on continuous vacuum cycles is performed.

As evident from the process sequence illustrated in FIG. 16(a), the pre-cleaning process in FIG. 16(a) is performed on a wiring pattern that has been processed into a dual-damascene structure as shown in FIG. 15(a). A SiOC film 202, interlayer insulation film 203, etching stopper film 204, interlayer insulation film 205 and copper-diffusion prevention film 206 are formed on a lower-layer copper wiring 201 to produce a copper-diffusion prevention layer. In this condition, surface treatment is performed using the surface treatment module 304 shown in FIG. 16(b) (under the same conditions as those described in Example 2).

FIG. 15(b) shows a condition immediately after the surface treatment. Here, a step of reducing the oxide formed on the surface of the copper wiring 203 at the bottom of via contacts 207, is performed simultaneously with a processing to stabilize the surface of the processed end of 202, 203, 204, 205 and 206 constituting the interlayer insulation film over trenches 208 and via contacts 207 in the dual-damascene structure. This processing forms NH or NH2 groups on the surface (where “x” is an integer of 1 or 2). Specifically, this processing is repeated continuously by means of plasma containing hydrogen gas or plasma containing N2, which reduces the surface of copper 201 at the bottom of via contacts 207.

In FIG. 15(c), a pre-treatment prior to the formation of Ru film, as shown in FIG. 16(a), is performed in the condition after completion of the above surface treatment. To be specific, a TaNC film 409 is formed for 20 cycles using Taimata, which is a metal-organic precursor, based on plasma ALD using hydrogen plasma (the film thickness in the figure is not scaled). Following the surface treatment using the surface treatment module 304 shown in FIG. 16(b), the substrate is transferred to the ALD module using metal-organic precursor 505 as shown in FIG. 16(b). Table 7 shows the conditions for TaNC film formation using Taimata and hydrogen plasma implemented here (the values shown in the table can be modified within a range of ±50%).

TABLE 7

| | | Flow rate | | | |
|---|---|---|---|---|---|
| Phase | Gas | (Sccm) | Temp. (° C.) | Pressure (Pa) | Time (sec) |
| Taimata | Taimata | 300 | 350 | 280 | 1 |
| dose | | | | | |
| Purge | Ar | 2000 | 350 | 150 | 1.0 |
| H2 Plasma | H2 | 1000 | 350 | 180 | 2.0 |
| Purge | Ar | 2000 | 350 | 150 | 1.0 |

Next in FIG. 15(d), a Ru film 410 is formed using the Ru-ALD module 506 shown in FIG. 16(b). Here, the Ru material shown in FIG. 3(a) was used, where the material was treated in a NH3 plasma process conforming to the sequence illustrated in FIG. 1(b). Table 6 (Example 2) shows the Ru-ALD process conditions (the values shown in the table can be modified within a range of ±50%). Although 700 W was used as the RF power of NH3 plasma, a Ru film can be formed in a RF power range of 200 W to 1,000 W. A similar process can also be achieved at a forming temperature in a range of 250 to 400° C. A Ru film with a thickness of approx. 1 nm was formed over 100 cycles.

FIG. 4 shows the change in sheet resistance when a Ru film was formed over 300 cycles under the conditions shown in Table 6 (refer to Example 2) on a 4-nm WNC film formed by ALC, as well as the change in sheet resistance when a Ru film was formed over 300 cycles under the conditions shown in Table 6 on a TaNC film formed over five, 10, 20 or 30 cycles under the conditions shown in Table 5. The sheet resistance when a Ru film was formed over 300 cycles by only introducing Taimata for 10 seconds, as explained in Example 2, is also shown. Although the WNC film was 4 nm thick, the TaNC film was formed over five to 30 cycles where the growth speed was approx. 0.06 nm/min. Accordingly, the estimated thickness of the TaNC film was 0.3 to 1.8 nm, which is clearly smaller than the thickness of the WNC film (desired effects can be achieved with a thickness of 2 nm or less). On the other hand, the results shown in FIG. 4 indicate that in the Ru layer structure, the sheet resistance decreased as the number of TaNC film formation cycles increased, although the specific resistance of the TaNC film (1 to 2 nm) was greater than the specific resistance of the 4-nm WNC film. This is probably because a Ru film grows easily on a Taimata-treated surface or surface on which a TaNC film has been formed using Taimata (this explanation is not intended to limit the present invention in any way). Therefore, a given embodiment of the present invention does not use a WNC film (W-type MO).

A Cu seed film 211 shown in FIG. 15(d) is formed on a wafer that has been transferred from the apparatus shown in FIG. 16(b), after which a copper plating film is formed as shown in FIG. 15(e), to form a copper wiring 212 through CMP. A Cu film can also be formed via Cu plating after the Ru film 410 has been formed, or a Cu plating can be formed directly on the Ru film 410. Also, a Cu film may be formed by CVD or ALD, instead of using PVD (the disclosure of U.S. patent application Ser. No. 11/469,828 owned by the same assignee as in the present application is incorporated herein by reference in its entirety).

As explained above, by continuously performing the series of steps including surface treatment, Taimata pre-treatment, Ru forming via ALD, and Cu plating, a Ru-PEALD film can be formed easily on the surface treated by the aforementioned process and consequently a low specific resistance can be achieved. Also, the Ru film that has been formed is dense, and thus can maintain high reliability. The Ru films formed by the aforementioned method exhibited a good copper-diffusion prevention effect even at a thickness of 2 to 4 nm. This is probably because entry of Ta atoms into the crystal grain boundary in the Ru film prevents Cu from diffusing (this explanation is not intended to limit the present invention in any way).

The above example discussed Taimata, and a TaNC film formed using Taimata. However, the same effect can also be achieved by using Ta(N-t-C4H9)[N(C2H5)2]3, Ta[N(CH3)2]5, Ta[N(C2H5)2]5, Hf[N(CH3)2]4, Hf[N(C2H5)2]4, Ti[N(CH3)2]4, Ti[N(C2H5)2]4, Nb[N(CH3)2]5, Nb[N(C2H5)2]5, Zr[N(CH3)2]4, or Zr[N(C2H5)2]4, instead of Taimata.

### EXAMPLE 4

This example shows an application of the present invention to the formation of a wiring process using a dual-damascene structure, which is the most commonly used copper wiring structure, and the effects of such application.

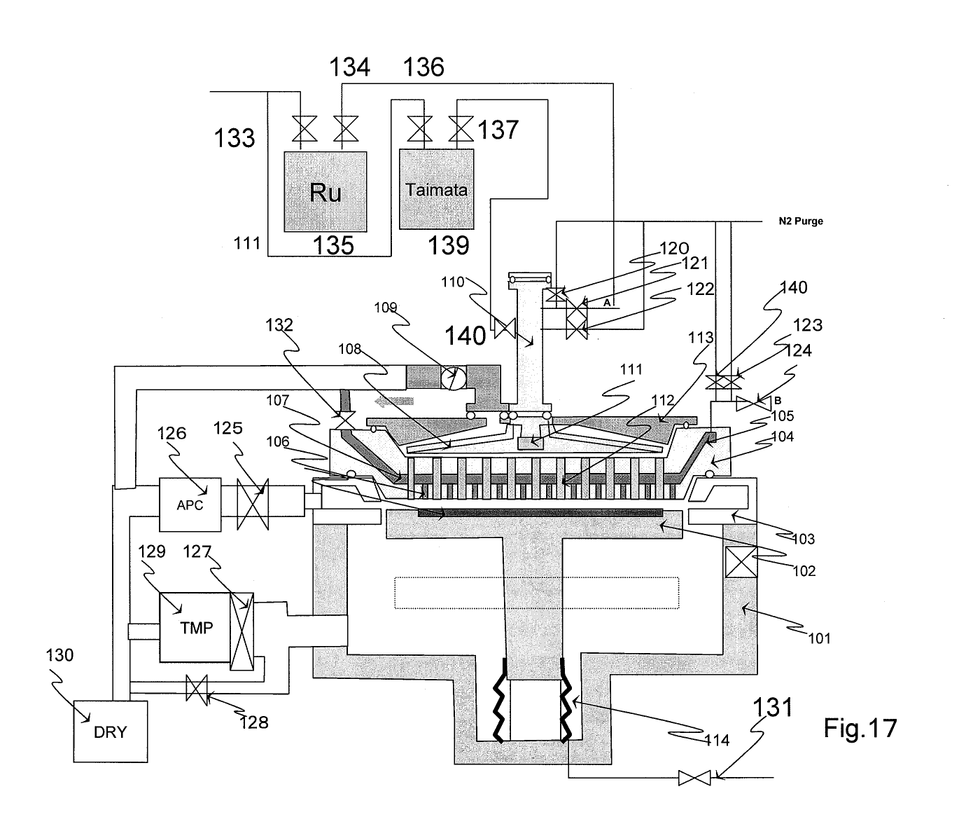

FIG. 17 shows a reaction module used in the sequence illustrated in FIG. 6, to form a Ru film after a pre-treatment using Taimata and then form a TaNC film using Taimata and hydrogen plasma, followed by formation of a Ru film, in conformance with the present invention. This module has a Taimata-material supply bottle 139 and a Ru metal-organic precursor bottle 135. To supply Taimata, valves 136, 137, 140 are opened to supply Taimata under bubbling.

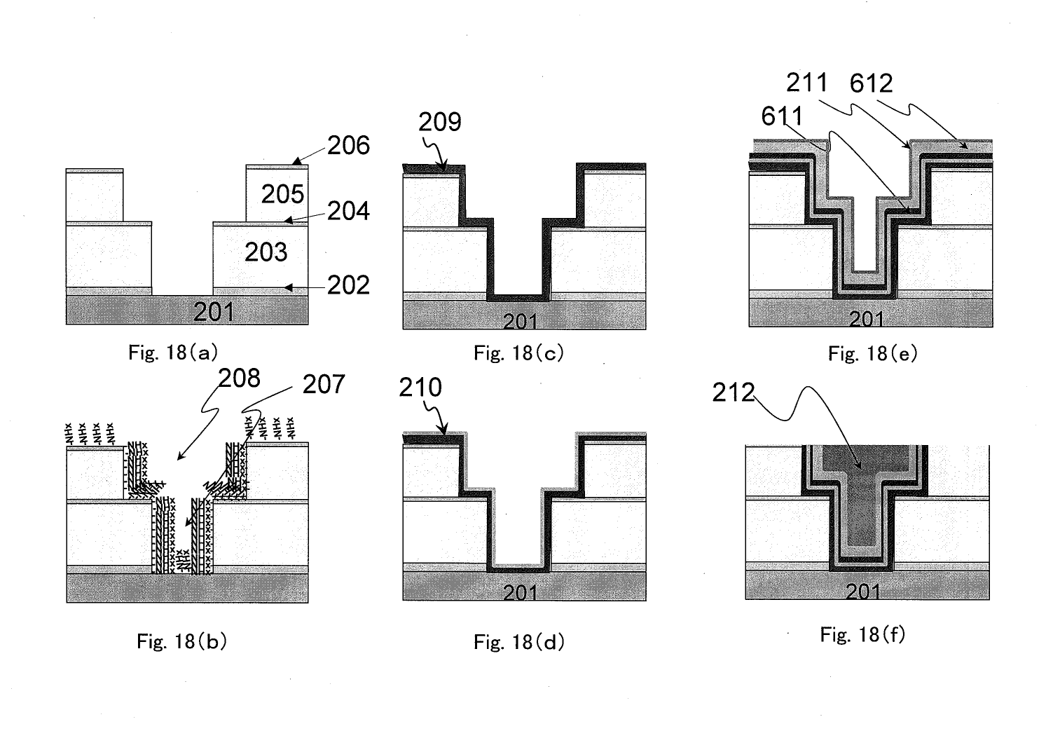

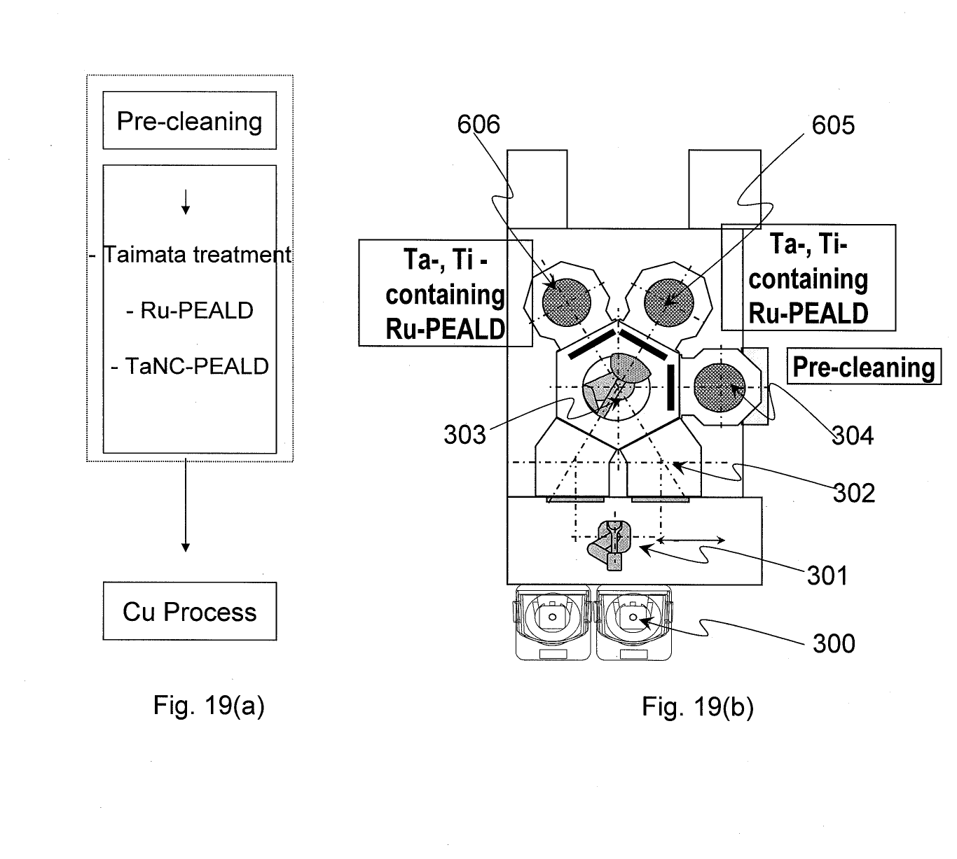

FIGS. 18(a) through (f) show a process to form a dual-damascene structure, illustrating a process flow starting from a condition after completion of dual-damascene processing. FIGS. 19(a) and (b) show the cluster process sequence and the structure of the cluster apparatus used in this example, respectively. The cluster apparatus shown in FIG. 19(b) comprises a pre-cleaning module 304, a module for pre-treatment using a Ta metal-organic precursor or for forming TaNC/TaN film 605, and a Ru forming module 606, and performs a process based on continuous vacuum cycles, as shown in FIG. 19(a).

FIG. 18(a) shows a condition after completion of dual-damascene processing. A SiOC film 202, interlayer insulation film 203, etching stopper film 204, interlayer insulation film 205 and copper-diffusion prevention film 206 are formed on a lower-layer copper wiring 201 to produce a copper-diffusion prevention layer. In this condition, surface treatment prior to the formation of ALD barrier film is performed using the surface treatment module 304 shown in FIG. 19(b).

FIG. 18(b) shows a condition immediately after the surface treatment. Here, a step of reducing the oxide formed on the surface of the copper wiring 203 at the bottom of via contacts 207, is performed simultaneously with a processing to stabilize the surface of the processed end of 202, 203, 204, 205 and 206 constituting the interlayer insulation film over trenches 208 and via contacts 207 in the dual-damascene structure. This processing forms NH or NH2 groups on the surface (where “x” is an integer of 1 or 2).

Next, processing using Taimata, which is a metal-organic precursor, is performed using either the processing apparatus 605 or 606 shown in FIG. 19(b), to form a pre-treatment layer 209 by Taimata (refer to Table 5 under Example 2). This way, Taimata adsorbs to the inner surface of via contacts and trenches. Adsorption of Taimata is denoted by 209.

Next in FIG. 18(d), a Ru film 210 is further formed using the Ru-ALD module 605 shown in FIG. 19(b) on the Taimata pre-treatment layer 209. Here, the Ru material shown in FIG. 3(a) was used, where the material was treated in a NH3 plasma process conforming to the sequence illustrated in FIG. 2(a) (refer to Table 4 under Example 2). Although 700 W was used as the RF power of NH3 plasma, a Ru film can be formed in a RF power range of 200 W to 1,000 W. A similar process can also be achieved at a forming temperature in a range of 250 to 400° C. A Ru film with a thickness of approx. 1 nm was formed over 100 cycles.

As shown in the sequence in FIG. 6, a TaNC film is formed via Taimata and hydrogen plasma using 605 or 606 in FIG. 19(b) in accordance with the sequence illustrated in Table 7 under Example 3. A very thin film can be formed after only five to 20 cycles or so. As shown in FIG. 18(e), a TaNC film 611 is formed on a Ru film 210, after which a Ru film 612 is formed over 20 to 100 cycles or so according to the sequence illustrated in Table 6 under Example 2. A film thickness of 1 nm is sufficient, and the film may be thinner than 1 nm.

A Cu seed film 211 shown in FIG. 18(e) is formed on a wafer that has been transferred from the apparatus shown in FIG. 19(b), after which a copper plating film is formed as shown in FIG. 18(f), to form a copper wiring 212 through CMP. A Cu film can also be formed via Cu plating after the Ru film 210 has been formed, or a Cu plating can be formed directly on the Ru film 210. Also, a Cu film may be formed by CVD or ALD, instead of using PVD.

As explained above, high reliability can be maintained by continuously performing the series of steps including surface treatment, Taimata pre-treatment, Ru forming via ALD, and Cu plating. This example described the sequence illustrated in FIG. 6, but the sequences shown in FIGS. 5, 7 and 8 can also be implemented in the same manner. In particular, use of the sequence illustrated in FIG. 5 allows a TaNC film, etc., to be included in the Ru film through a Ru surface treatment using a gas such as Ta(N-t-C4H9)[N(C2H5)2]3, Ta[N(CH3)2]5, Ta[N(C2H5)2]5, Hf[N(CH3)2]4, Hf[N(C2H5)2]4, Ti[N(CH3)2]4, Ti[N(C2H5)2]4, Nb[N(CH3)2]5, Nb[N(C2H5)2]5, Zr[N(CH3)2]4, and Zr[N(C2H5)2]4, and Al(CH3)3, thereby improving the Cu diffusion barrier property of the Ru film. The Ru film formed by the aforementioned method has a net thickness of only 2 nm. It is considered that entry of Ta atoms into the crystal grain boundary in the Ru film prevents Cu from diffusing (this explanation is not intended to limit the present invention in any way).

The above example discussed Taimata, and a TaNC film formed using Taimata. However, the same effect can also be achieved by using Ta(N-t-C4H9)[N(C2H5)2]3, Ta[N(CH3)2]5, Ta[N(C2H5)2]5, Hf[N(CH3)2]4, Hf[N(C2H5)2]4, Ti[N(CH3)2]4, Ti[N(C2H5)2]4, Nb[N(CH3)2]5, Nb[N(C2H5)2]5, Zr[N(CH3)2]4, or Zr[N(C2H5)2]4, instead of Taimata.

The present invention includes the above mentioned embodiments and other various embodiments including the following:

1) A method of forming a metal film, and a metal film, characterized by, in a method of forming Ru film comprising a first step of supplying a first metal material gas to the surface of a substrate, a second step of supplying a gas of a metal-organic precursor containing Ru to the substrate, and a third step of treating the substrate using a reducing gas excited by high-frequency waves, repeating the second step and third step at least once.

2) A method of forming a metal film, and a metal film, characterized by repeating at least once a step of supplying a first metal material gas to the surface of a substrate and a step of subsequently supplying a reactive gas to form on the substrate surface a metal containing a metal element constituting the metal material, and then repeating at least once a third step of supplying a gas of a metal-organic precursor containing Ru to the substrate and a fourth step of treating the substrate using a reducing gas excited by high-frequency waves to form a Ru film on the metal.

3) A method of forming a metal film, and a metal film, according to 1) above, characterized in that the first metal-organic precursor is a metal-organic precursor molecule constituted by Ta, Hf, Zr, Ti, or Nb.

4) A method of forming a metal film, and a metal film, according to 2) above, characterized in that the first metal material is a molecule constituted by W, Ta, Hf, Zr, Ti, or Nb.

5) A method of forming a metal film, and a metal film, according to 1) or 2) above, characterized in that the metal-organic precursor containing Ru has a Ru(XaXb) structure where at least one of Xa or Xb is selected from molecules having a pentadienyl.

6) A method of forming a metal film, and a metal film, according to 1) or 2) above, characterized in that the reducing gas contains either H2 or NH3.

7) A method of forming a metal film, and a metal film, according to 3) or 4) above, characterized in that the metal-organic precursor molecule constituted by Ta, Hf, Zr, Ti or Nb is selected from Ta(N-t-C5H11)[N(CH3)2]3, Ta(N-t-C4H9)[N(C2H5)2]3, Ta[N(CH3)2]5, Ta[N(C2H5)2]5, Nb[N(CH3)2]5, Nb[N(C2H5)2]5, Hf(N(CH3)2)4, Hf[N(C2H5)2]4, Ti[N(CH3)2]4, Ti[N(C2H5)2]4, Nb[N(CH3)2]5, Nb[N(C2H5)2]5, Zr[N(CH3)2]4, and Zr[N(C2H5)2]4.

8) A method of a forming metal film, and a metal film, according to 4) above, characterized in that the first metal film is constituted by any one of WNC, WN, WC, TaN, TaC, TaNC, Ti, TiN, TiNC, HfN, HFNC, ZrN, ZrNC, NbN, and NbNC.

9) A method of a forming metal film, and a metal film, according to 1) above, characterized in that a metal film mainly constituted by Ru is formed by repeating the second step and third step at least once.

10) A method of forming a metal film, and a metal film, according to 2) above, characterized in that a metal film mainly constituted by Ru is formed by repeating the third step and fourth step at least once.

11) A method of forming a metal film, and a metal film, according to 10) above, characterized in that the first metal film is thinner than the metal film mainly constituted by Ru.

12) A method of forming a metal film, and a metal film, according to 11) above, characterized in that the first metal film is 1 nm or thinner and the metal film mainly constituted by Ru is thicker than the first metal film and having a thickness of 1 nm or more.

13) A method of forming a metal film, and a metal film, according to 10) or 11) above, characterized in that the metal film mainly constituted by Ru is 0.5 nm or thicker.

14) A method of forming a metal film, and a metal film, according to any one of 9) through 13) above, characterized in that the metal film mainly constituted by Ru contains Al, Ti, Ta, Hf, Nb, or Zr.

15) A method of forming a Ru film and a Ru film formed using said formation method according to the foregoing, characterized in that the Ru film is formed by repeating for no less than 50 cycles but no more than 150 cycles, or preferably no less than 75 cycles but no more than 100 cycles, a step of supplying the Ru material gas to a substrate, and a step of treating the top face of the substrate using a gas containing at least NH3 or H2 and excited by high-frequency waves.

16) A method of forming a Ru film and a Ru film formed using said formation method according to any one of the foregoing, characterized in that the pentadienyl group has a side chain with a carbon number of 1 or above bonded to it.

17) A method of forming a Ru film and a Ru film formed using said formation method according to any one of the foregoing, characterized in that a copper film is formed on the Ru film.

18) A method of forming a Ru film and a Ru film formed using said formation method according to 17) above, characterized in that the copper film is formed on the Ru film by means of the chemical vapor deposition or atomic layer deposition method, based on a supply of copper material molecules into vacuum in gaseous form.

It will be understood by those of skill in the art that numerous and various modifications can be made without departing from the spirit of the present invention. Therefore, it should be clearly understood that the forms of the present invention are illustrative only and are not intended to limit the scope of the present invention.

What is claimed is:

1. A method of depositing a ruthenium (Ru) thin film on a substrate, comprising:
(i) treating a surface of the substrate with a metal-organic precursor;
(ii) adsorbing a ruthenium precursor onto the treated surface of the substrate;
(iii) treating the adsorbed ruthenium precursor with an excited reducing gas;
and
(iv) repeating steps (ii) and (iii), thereby forming a ruthenium thin film on the substrate.

2. The method according to claim 1, wherein step (i) comprises exposing the surface of the substrate to a gas of the metal-organic precursor to adsorb the metal-organic precursor on the substrate surface.

3. The method according to claim 2, wherein the metal-organic precursor contains Ta, Hf, Zr, Nb, or Ti.

4. The method according to claim 1, wherein step (i) comprises:
(a) adsorbing the metal-organic precursor onto the surface of the substrate;
(b) treating the adsorbed metal-organic precursor with a reactive gas; and
(c) repeating steps (a) and (b), thereby forming a metal film on the substrate.

5. The method according to claim 4, wherein the metal film contains W, Ta, Hf, Zr, Nb, or Ti.

6. The method according to claim 4, wherein the metal film is formed by atomic layer deposition (ALD).

7. The method according to claim 5, wherein the metal film is selected from the group consisting of TaN, TaNC, TiN, and TiNC.

8. The method according to claim 1, wherein the ruthenium precursor is a ruthenium complex containing a non-cyclic dienyl.

9. The method according to claim 8, wherein the ruthenium complex has a structure of Xa-Ru-Xb, wherein at least one of Xa or Xb is a non-cyclic dienyl.

10. The method according to claim 9, wherein the non-cyclic dienyl is a non-cyclic pentadienyl.

11. The method according to claim 1, wherein the excited reducing gas is generated by applying radio-frequency power to a reducing gas.

12. The method according to claim 11, wherein the reducing gas is ammonia, hydrogen, or a mixture of nitrogen and hydrogen.

13. The method according to claim 11, wherein the excited reducing gas is an ammonia or hydrogen plasma.

14. The method according to claim 1, further comprising purging the ruthenium precursor gas from a reaction chamber after step (ii) and purging the excited reducing gas from the reaction chamber after step (iii).

15. The method according to claim 1, wherein steps (ii) and (iii) are repeated to form the ruthenium thin film having a thickness of no less than 0.5 nm but no more than 2.0 nm by atomic layer deposition (ALD).

16. The method according to claim 1, wherein the ruthenium thin film is formed on and in contact with the underlying layer formed by step (i), wherein a thickness of the ruthenium thin film is greater than that of the underlying layer.

17. The method according to claim 1, further comprising treating the substrate surface with a metal-organic precursor after step (iv) and resuming step (iv).

18. The method according to claim 17, wherein the metal-orgnic precursor contains Al, Ti, Ta, Hf, Nb, or Zr.

19. The method according to claim 1, wherein steps (i) to (iv) are repeated to form a layered structure.
